(19) United States
(12) Patent Application Publication
(10) Pub. No.: US 2010/0275990 A1
(43) Pub. Date: Nov. 4, 2010

(54) PHOTOELECTRIC CONVERSION DEVICE AND MANUFACTURING METHOD THEREOF

(75) Inventors: Akihisa SHIMOMURA, Atsugi (JP); Fumito ISAKA, Zama (JP); Sho KATO, Ebina (JP)

Correspondence Address: NIXON PEABODY, LLP, 401 9TH STREET, NW, SUITE 900, WASHINGTON, DC, 20004-2128, US

(73) Assignee: SEMICONDUCTOR ENERGY LABORATORY CO., LTD., Atsugi-shi (JP)

(21) Appl. No.: 12/768,351

(22) Filed: Apr. 27, 2010

(30) Foreign Application Priority Data
May 2, 2009 (JP) 2009-112372

(51) Int. Cl. H01L 31/00; H01L 21/78; H01L 31/18

(52) U.S. Cl. 136/256; 438/68; 257/E21.599

(57) ABSTRACT

To provide a novel photoelectric conversion device and a manufacturing method thereof. Over a base substrate having a light-transmitting property, a light-transmitting insulating layer and a single crystal semiconductor layer over the insulating layer are formed. A plurality of first impurity semiconductor layers each having one conductivity type is provided in a band shape in a surface layer of the single crystal semiconductor layer or on a surface of the single crystal semiconductor layer, and a plurality of second impurity semiconductor layers each having a conductivity type which is opposite to the one conductivity type is provided in a band shape in such a manner that the first impurity semiconductor layers and the second impurity semiconductor layers are alternately provided and do not overlap with each other. First electrodes in contact with the first impurity semiconductor layers and second electrodes in contact with the second impurity semiconductor layers are provided, and a back contact cell is formed, whereby a photoelectric conversion device provided with a photo acceptance surface on the base substrate side is formed.

### BACKGROUND OF THE INVENTION

1. Field of the Invention

The present invention relates to a photoelectric conversion device and a manufacturing method thereof.

2. Description of the Related Art

Global warming has advanced, and energy sources which replace fossil fuels have been reviewed. Of them, a photoelectric conversion device which is also called a solar battery holds the greatest promise as a typical electric power generating means in the next generation. In recent years, research and development of the device has been actively carried out, and a market has rapidly expanded.

The photoelectric conversion devices are attractive power generation means which use inexhaustible sunlight as energy sources and which do not emit carbon dioxide at the time of power generation. However, there are problems in that photoelectric conversion efficiency per unit area is not sufficient, that the amount of power generation is affected by the daylight hours under present conditions and the like, so that a long time of around 20 years is needed for recovery of the initial cost. This problem is an obstacle to widespread use of the photoelectric conversion devices for conventional homes, and high efficiency and low cost of the photoelectric conversion devices are required.

The photoelectric conversion devices can be formed using a silicon-based material or a compound-based semiconductor material, and silicon-based solar cells such as bulk silicon solar cells and thin film silicon solar cells are mainly commercialized. The bulk silicon solar cells formed using a single crystal silicon wafer or a polycrystalline silicon wafer have relatively high conversion efficiency. However, a region which is actually utilized for photoelectric conversion is just part of the silicon wafer in a thickness direction, and the other region just contributes as a support having conductivity. A loss of a cutting margin portion when the silicon wafer is cut out from an ingot, necessity of polishing process, and the like are factors that makes it impossible to decrease the cost of the bulk silicon solar cells.

On the other hand, the thin film silicon solar cells can be formed in such a way that a silicon thin film is formed using required amount of silicon employing a plasma enhanced CVD method or the like. Integration is easily performed by a laser processing method, a screen printing method, or the like, and compared with the bulk silicon solar cell, production costs of the thin film silicon solar cells can be reduced in terms of resource saving, large areas, and the like. However, the thin film silicon solar cells have a disadvantage in lower conversion efficiency than the bulk silicon solar cells.

In order to achieve low cost while high photoelectric efficiency is kept, a method for manufacturing solar cells has been proposed in which hydrogen ions are implanted into a crystalline semiconductor and the crystalline semiconductor is cut by heat treatment to obtain a crystalline semiconductor layer which serves as a photoelectric conversion layer (e.g., see Patent Document 1). The crystalline semiconductor to which ions of a predetermined element are implanted in a layer shape is attached on an insulating layer over a substrate with a conductive adhesive interposed therebetween, and the crystalline semiconductor and the insulating layer are fixed employing heat treatment of higher than or equal to 300° C. and lower than or equal to 500° C. Next, voids are formed in the region where the ions of the predetermined element are implanted to the crystalline semiconductor in the layer shape with heat treatment of higher than or equal to 500° C. and lower than or equal to 700° C., and further the crystalline semiconductor is separated at the voids using a heat strain, so that a crystalline semiconductor layer which serves as a photoelectric conversion layer is formed over the substrate.

As a structure which takes sunlight in a photoelectric conversion device without waste, a back contact structure in which a collection electrode is not formed on a photo acceptance surface and there is no shadow loss has been proposed (e.g., see Non Patent Document 1). In this back contact structure, not only a semiconductor junction which forms an internal electric field but also all the electrodes are provided on the back side of the photo acceptance surface. Only a textured structure or a passivation layer which is used to prevent reflection and recombination of carriers is formed on the surface side, so that a loss due to the structure of a cell is removed as much as possible, and high conversion efficiency is obtained.

A method has also been proposed in which a single crystal silicon wafer whose surface layer is a porous layer is used as a seed layer, a single crystal silicon layer is epitaxially grown, a photoelectric conversion element is formed using the single crystal silicon layer which has been formed, and then the substrate is attached to another substrate and separation is performed at a porous portion (e.g., see Patent Document 2). The porous layer is formed by anodization of a single crystal wafer, and the single crystal silicon is epitaxially grown over the porous layer employing a vapor phase method or a liquid phase method. Next, a pattern is formed using a low-resistance material including an n-type or p-type dopant, and an impurity layer having one conductivity type and an electrode are formed by heating of the single crystal silicon wafer. Next, the entire surface is covered with an insulating layer, and then a region other than the electrode which has been formed is partly opened, and an impurity layer having a conductivity type which is opposite to the one conductivity type is liquid phase grown. A back contact photoelectric conversion device formed in this way is attached to a supporting substrate with a conductive adhesive, and separation is performed at the porous layer. The separated silicon wafer is used plural times by repeating similar steps.

### [References]

### [Patent Document]

[Patent Document 1] Japanese Published Patent Application No. H10-335683
[Patent Document 2] Japanese Published Patent Application No. H11-214720

### [Non-Patent Document]

[Non-Patent Document 1] R. A. Sinton, Young Kwark, J. Y. Gan, and Richard M. Swanson, “27.5-Percent Silicon Concentrator Solar Cells”, IEEE Electron Device Lett., vol. EDL-7, No. 10, pp. 567-569, October 1986

### SUMMARY OF THE INVENTION

A conventional photoelectric conversion device in which a silicon wafer is made thin has a structure in which a conductive adhesive is used for attaching a substrate which serves as a support and a silicon semiconductor layer. When a module is formed using the photoelectric conversion device, a structure is required to have resistance to bending or twist because materials which have several kinds of properties are stacked. In terms of resistance to environment, one of the important objects is to secure, in particular, resistance to bending or twist due to a temperature change.

Since a filler metal used for the conductive adhesive has almost no transmissivity in an absorption wavelength range of the photoelectric conversion device, a structure is formed in which a photo acceptance surface is provided not on the supporting substrate side but on the surface side of the semiconductor layer. This structure is referred to as a substrate system, and the photo acceptance surface is sealed with a light-transmitting resin or the like, so that a modular structure is completed. The substrate structure has characteristics of thin and light weight; on the other hand, there is a problem of low resistance to bending, twist, pressing force, or the like. A lot of modules having a super-straight structure with high mechanical strength, in which a photo acceptance surface is provided on the supporting substrate side, are used for photoelectric conversion devices installed on a roof of a building or the like.

On the other hand, a thin film silicon solar cell is easily integrated in a large area employing a laser processing method, a screen printing method, or the like, and a module having a super-straight structure with high mechanical strength is easily formed. However, it is difficult to form a single crystal silicon film having high photoelectric conversion efficiency in a large area in a manner similar to that of a non-single-crystal silicon film, which is a significant challenge.

In view of the foregoing problems, an object of one embodiment of the present invention is to provide a photoelectric conversion device of resource saving type making good use of a semiconductor material. Another object of one embodiment of the present invention is to provide a photoelectric conversion device whose mechanical strength is high and whose photoelectric conversion efficiency is improved.

According to one embodiment of the present invention, a photoelectric conversion device is provided with a photoelectric conversion layer which uses a single crystal semiconductor layer as a light absorption layer over a light-transmitting insulating substrate, and a photo acceptance surface on the light-transmitting insulating substrate side. In addition, a photoelectric conversion module is formed in which a plurality of the photoelectric conversion layers is provided over the same light-transmitting insulating substrate and the photoelectric conversion layers are electrically connected to each other.

Note that the term “photoelectric conversion layer” in this specification includes a semiconductor layer which shows a photoelectric effect (internal photoelectric effect) and moreover includes a semiconductor junction for forming an internal electric field. That is, the photoelectric conversion layer refers to a semiconductor layer having a junction typified by a p-n junction, a p-i-n junction, or the like.

First, a structure of a photoelectric conversion device which uses a single crystal semiconductor formed over a light-transmitting insulating substrate as a light absorption layer is described. Over the light-transmitting insulating substrate, a light-transmitting insulating layer and a single crystal semiconductor layer which is fixed with the insulating layer interposed between the light-transmitting insulating substrate and the single crystal semiconductor layer are formed. The single crystal semiconductor layer is formed in such a way that a sliced single crystal semiconductor substrate, which is used as a seed layer, is epitaxially grown and made thick.

A plurality of first impurity semiconductor layers each having one conductivity type is provided in a band shape in the surface layer or on the surface of the single crystal semiconductor layer. In addition, a plurality of second impurity semiconductor layers each having a conductivity type which is opposite to the one conductivity type is provided in a band shape in a manner that the first impurity semiconductor layers and the second impurity semiconductor layers are alternately provided and do not overlap with each other. Here, the single crystal semiconductor layer, the first impurity semiconductor layers, and the second impurity semiconductor layers form a photoelectric conversion layer. A photoelectric conversion device is formed in which first electrodes which are in contact with the first impurity semiconductor layers and second electrodes which are in contact with the second impurity semiconductor layers are provided and a photo acceptance surface is provided on the base substrate side.

A photoelectric conversion module can also be formed in which a plurality of the photoelectric conversion layers is formed over the light-transmitting insulating substrate and an electrode layer which connects the adjacent photoelectric conversion layers in series and/or in parallel is provided.

Next, a method for manufacturing the photoelectric conversion device and the photoelectric conversion module will be described. A light-transmitting insulating layer is formed on a surface, an embrittlement layer is formed in a region at a predetermined depth, a plurality of single crystal semiconductor substrates each having a first conductivity type, and a light-transmitting insulating substrate which serves as a base substrate are prepared. The plurality of single crystal semiconductor substrates is arranged over the base substrate with an insulating layer interposed therebetween at predetermined intervals, and the surface of the insulating layer is bonded to the surface of the base substrate, whereby the plurality of single crystal semiconductor substrates is attached on the base substrate. Part of the plurality of single crystal semiconductor substrates is separated from the base substrate at the embrittlement layer, so that a plurality of stack bodies in each of which the insulating layer and a first single crystal semiconductor layer are stacked is formed over the base substrate.

Note that the term “embrittlement layer” in this specification refers to a weakened region in which a crystal structure is locally disordered and includes a region at which a single crystal semiconductor substrate is separated into a single crystal semiconductor layer and a separation substrate (a single crystal semiconductor substrate) in a separation process, and its vicinity.

Here, the embrittlement layer can be formed by introducing hydrogen, helium and/or a halogen into the inside of the single crystal semiconductor substrate. Alternatively, the embrittlement layer can be formed by scanning with a laser beam that allows multiphoton absorption, while a focal point of the laser beam is focused inside the single crystal semiconductor substrate. A glass substrate is preferably used for the light-transmitting insulating substrate to serve as the base substrate.

Next, for the plurality of stack bodies each formed using the insulating layer and the first single crystal semiconductor layer, which is arranged at predetermined intervals, a process of recovering crystallinity of the first single crystal semiconductor layer which is an outermost surface layer and a process of recovering planarity are performed. When a laser beam is emitted from an upper surface side of the first single crystal semiconductor layer, the first single crystal semiconductor layer is melted and then solidified; therefore, the crystallinity and planarity of the first single crystal semiconductor layer can be improved.

As the laser beam applicable to the laser treatment, a laser beam having a wavelength that is absorbed by the single crystal semiconductor layer is employed. The wavelength of a laser beam can be determined in consideration of the skin depth of the laser beam, or the like. For example, a laser having a wavelength from an ultraviolet light region to a visible light region is selected.

Next, a semiconductor layer is formed so as to cover the entire surface of the substrate including the plurality of stack bodies each formed using the insulating layer and the first single crystal semiconductor layer. As this time, a second single crystal semiconductor layer which is single-crystallized is fanned over at least the first single crystal semiconductor layer. In addition, the semiconductor layer formed in the spaces of the stack bodies is selectively etched, and the stack bodies are separated again into individual stack bodies.

A non-single-crystal semiconductor layer is formed, and then the second single crystal semiconductor layer can be foamed from the non-single-crystal semiconductor layer using solid phase epitaxial growth by heat treatment. Alternatively, the second single crystal semiconductor layer can be formed using gas phase epitaxial growth employing a plasma enhanced CVD method or the like.

Next, over the surface of the second single crystal semiconductor layer or the surface layer of the second single crystal semiconductor layer, a plurality of impurity semiconductor layers each having one conductivity type and a plurality of impurity semiconductor layers each having a conductivity type which is opposite to the one conductivity type are provided in a band shape in a manner that the impurity semiconductor layers each having the one conductivity type and the impurity semiconductor layers each having the conductivity type which is opposite to the one conductivity type do not overlap with each other. Then, semiconductor junctions are formed between the second single crystal semiconductor layer and the impurity semiconductor layers each having the one conductivity type and the impurity semiconductor layers each having the conductivity type which is opposite to the one conductivity type, or inside the second single crystal semiconductor layer. Further, the first electrodes and the second electrodes which are in contact with the impurity semiconductor layers each having the one conductivity type and the impurity semiconductor layers each having the conductivity type which is opposite to the one conductivity type, respectively, are formed over the semiconductor layer, so that a back contact photoelectric conversion device is formed.

The impurity semiconductor layers each having one conductivity type and the impurity semiconductor layers each having a conductivity type which is opposite to the one conductivity type are provided in the surface layer of the second single crystal semiconductor layer in such a manner that an element imparting a conductivity type is introduced to the surface layer of the second single crystal semiconductor layer. In addition, the impurity semiconductor layers each having one conductivity type and the impurity semiconductor layers each having a conductivity type which is opposite to the one conductivity type are provided on the surface of the second single crystal semiconductor layer in such a manner that a semiconductor film which includes an element imparting a conductivity type to a semiconductor is formed on the surface of the second single crystal semiconductor layer.

Next, in the adjacent photoelectric conversion layers over the substrate, a first connection electrode which connects the first electrode provided for one photoelectric conversion layer and the second electrode provided for the other photoelectric conversion layer is provided. Besides, a second connection electrode which connects the first electrodes provided for the adjacent photoelectric conversion layers and which connects the second electrodes provided for the adjacent photoelectric conversion layers is provided. The modular structure in which the first connection electrode and the second connection electrode thus formed are combined and desired voltage and current can be taken out is formed.

It is preferable that the first connection electrode and the second connection electrode be the same layer as that of the first electrode and the second electrode.

In the above-mentioned structure, there is no limitation on the conductivity types of the first single crystal semiconductor layer and the second single crystal semiconductor layer. The first single crystal semiconductor layer is a thin seed layer which is used for substantially growing the second single crystal semiconductor layer, and the first single crystal semiconductor layer having any of conductivity types has small contribution to substantial photoelectric conversion. Even if the second single crystal semiconductor layer has any of conductivity types, an internal electric field can be generated when a junction is formed with a semiconductor layer having a conductivity type which is opposite to that of the second single crystal semiconductor layer.

The term “single crystal” or “single-crystal” in this specification refers to a crystal in which crystal faces and crystal axes are aligned and atoms or molecules which are included in the single crystal are aligned in a spatially ordered manner. A single crystal including a lattice defect in which the alignment is partly disordered, a single crystal including intended or unintended lattice distortion, and the like are not excluded.

In this specification, a numeral such as “first” and “second” which are included in a term is given for convenience in order to distinguish elements, does not limit the number and does not limit the arrangement and the order of the steps.

According to one embodiment of the present invention, a photoelectric conversion device can be provided in which a single crystal semiconductor is used for a photoelectric conversion layer and high efficiency and resource saving are attempted. When a light-transmitting insulating substrate is used as a supporting substrate and a semiconductor junction and an electrode are formed on the surface side of a semiconductor layer, a structure in which light enters on the substrate side, which has been difficult in a conventional structure, can be formed and a modular structure having high mechanical strength can be obtained. In addition, photoelectric conversion devices can be completed in a batch process for a plurality of single crystal semiconductor layers formed over a large-area substrate, and a method for manufacturing a photoelectric conversion device, the integration process of which is easy, can be provided.

### BRIEF DESCRIPTION OF THE DRAWINGS

FIG. 1 is a cross-sectional schematic view illustrating a photoelectric conversion device according to one embodiment of the present invention.

FIG. 2 is a plan schematic view illustrating a photoelectric conversion device according to one embodiment of the present invention.

FIGS. 3A to 3C are cross-sectional views illustrating a method for manufacturing a photoelectric conversion device according to one embodiment of the present invention.

FIGS. 4A and 4B are cross-sectional views illustrating the method for manufacturing the photoelectric conversion device according to the one embodiment of the present invention.

FIGS. 5A and 5B are cross-sectional views illustrating the method for manufacturing the photoelectric conversion device according to the one embodiment of the present invention.

FIGS. 6A and 6B are cross-sectional views illustrating the method for manufacturing the photoelectric conversion device according to the one embodiment of the present invention.

FIGS. 7A and 7B are cross-sectional views illustrating the method for manufacturing the photoelectric conversion device according to the one embodiment of the present invention.

FIG. 8 is a plan view illustrating the method for manufacturing the photoelectric conversion device according to the one embodiment of the present invention.

FIGS. 9A and 9B are cross-sectional views illustrating a method for manufacturing a photoelectric conversion device according to one embodiment of the present invention.

FIGS. 10A and 10B are cross-sectional views illustrating a method for manufacturing a photoelectric conversion device according to one embodiment of the present invention.

FIGS. 11A to 11D are views illustrating examples in which a single crystal semiconductor substrate having a predetermined shape is cut out of a circular single crystal semiconductor substrate.

FIGS. 12A to 12C are cross-sectional views illustrating a method for manufacturing a photoelectric conversion device according to one embodiment of the present invention.

FIG. 13 is a cross-sectional view illustrating a photoelectric conversion device according to one embodiment of the present invention.

FIGS. 14A to 14C are cross-sectional views illustrating a method for manufacturing a photoelectric conversion device according to one embodiment of the present invention.

FIG. 15 is a cross-sectional view illustrating a manufacturing method of another embodiment of an embrittlement layer.

FIGS. 16A and 16B are cross-sectional view each illustrating a photoelectric conversion device according to one embodiment of the present invention.

FIG. 17 is a cross-sectional view illustrating a planarizing method of a semiconductor surface by laser irradiation.

FIGS. 18A and 18B are cross-sectional view illustrating a planarizing method of a semiconductor surface by etching.

### DETAILED DESCRIPTION OF THE INVENTION

Embodiments of the present invention will be described with reference to the drawings. However, the present invention is not limited to the description below, and it is to be easily understood by those skilled in the art that various changes in modes and details thereof will be apparent without departing from the spirit and scope of the present invention. Therefore, the present invention should not be construed as being limited to the description in the following embodiments. Note that in the structures of the present invention described below, the reference numerals indicating the same are used in common in the drawings.

### Embodiment 1

One embodiment of the present invention is a photoelectric conversion device having a single crystal semiconductor layer. A light-transmitting insulating substrate is used as a supporting substrate, semiconductor junctions and electrodes are formed on the surface side of the semiconductor layer, and a photo acceptance surface is provided on the supporting substrate side.

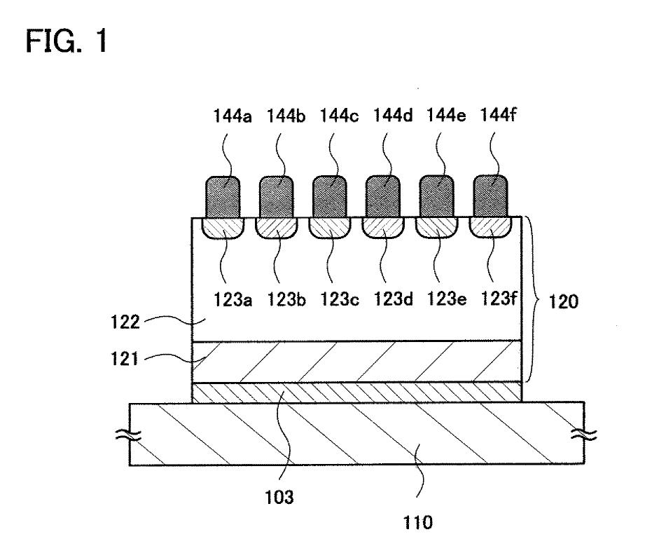

A cross-sectional view of a photoelectric conversion device provided with a photoelectric conversion layer over a base substrate is illustrated in FIG. 1. There are no particular limitations on the planar shape of the photoelectric conversion layer, and a rectangular shape including a square, a polygonal shape, or a circular shape can be employed.

There are no particular limitations on a base substrate 110 as long as the substrate can withstand a manufacturing process of a photoelectric conversion device according to one embodiment of the present invention and can have a light-transmitting property; for example, a light-transmitting insulating substrate can be used. Specifically, a quartz substrate; a ceramic substrate; a sapphire substrate; a variety of glass substrates used in the electronics industry, such as aluminosilicate glass, aluminoborosilicate glass, or barium borosilicate glass; and the like are given as examples. A glass substrate, which can have a large area and is inexpensive, is preferably used because a cost reduction and productivity improvement can be achieved.

As in a cross-sectional view illustrated in FIG. 1, a photoelectric conversion device is formed in such a manner that, over the base substrate 110, a photoelectric conversion layer 120 is formed using a single crystal semiconductor layer that is fixed to the base substrate 110 with an insulating layer 103 interposed between the base substrate 110 and the photoelectric conversion layer 120. Then, first electrodes 144a, 144c, and 144e and second electrodes 144b, 144d, and 144f are provided using conductive materials over the photoelectric conversion layer 120. Here, the electrodes are selectively formed over a plurality of impurity semiconductor layers in a band shape in the surface layer of the photoelectric conversion layer 120. Because the impurity semiconductor layers have high electric resistance, the electrodes are preferably formed also in a band shape.

The photoelectric conversion layer 120 includes a first single crystal semiconductor layer 121, a second single crystal semiconductor layer 122, first impurity semiconductor layers 123a, 123c, and 123e each having one conductivity type, and second impurity semiconductor layers 123b, 123d, and 123f each having a conductivity type which is opposite to the one conductivity type.

Here, the first impurity semiconductor layers and the second impurity semiconductor layers formed in the surface layer of the second single crystal semiconductor layer 122 are not limited to FIG. 1 in number as an example, but can be increased or decreased depending on size and crystallinity of the photoelectric conversion layer. It is preferable that a plurality of the impurity semiconductor layers having the same conductivity type be formed in a band shape on the entire surface of the photoelectric conversion layer at intervals of greater than or equal to 0.1 mm and less than or equal to 10 mm, more preferably, greater than or equal to 0.5 mm and less than or equal to 5 mm. It is also preferable that the first impurity semiconductor layers each having one conductivity type and the second impurity semiconductor layers each having a conductivity type which is opposite to the one conductivity type be formed so as not to overlap with each other.

When the second single crystal semiconductor layer 122 has an n-type or p-type conductivity type, p-n junctions are formed near the first impurity semiconductor layers or near the second impurity semiconductor layers. The exemplified bonding areas of the first impurity semiconductor layers and the second impurity semiconductor layers are the same; however, the area on the p-n junction side may be increased in order to extract carriers which are photoinduced with as little recombination as possible. Therefore, the first impurity semiconductor layers and the second impurity semiconductor layers are not necessarily the same in number and shape. A large area on the p-i junction side enables carriers to be extracted with as little recombination as possible even when the second single crystal semiconductor layer 122 has i-type conductivity because the life of a hole is shorter than that of an electron. Also in this case, the first impurity semiconductor layers and the second impurity semiconductor layers are not necessarily the same in number and shape as in the case of the p-n junctions.

The first single crystal semiconductor layer 121 is formed from a single crystal semiconductor layer which is sliced off from a single crystal semiconductor substrate. Typically, a single crystal silicon layer which is sliced off from a single crystal silicon substrate is used to form the first single crystal semiconductor layer 121. In this embodiment, the first single crystal semiconductor layer 121 is utilized as a seed layer when the second single crystal semiconductor layer 122 to substantially serve as a light absorption layer is grown. Alternatively, a polycrystalline semiconductor substrate (typically a polycrystalline silicon substrate) can be used instead of the single crystal semiconductor substrate. In this case, a region corresponding to the first single crystal semiconductor layer 121 is formed from a polycrystalline semiconductor layer (typically, a polycrystalline silicon layer).

The second single crystal semiconductor layer 122 is formed as follows: a crystal of a single crystal semiconductor layer is grown employing an epitaxial growth technique such as solid phase epitaxy or vapor phase epitaxy. The thickness of the photoelectric conversion layer including the first single crystal semiconductor layer 121 and the second single crystal semiconductor layer 122 is greater than or equal to 1 μm and less than or equal to 10 μm, preferably, greater than or equal to 2 μm and less than or equal to 8 μm.

Although there is no limitation on the conductivity type of the first single crystal semiconductor layer 121, a single crystal semiconductor layer which is formed using a sliced p-type single crystal silicon substrate is used. Although there is no limitation on the conductivity type of the second single crystal semiconductor layer 122, an i-type single crystal semiconductor layer is used here. Note that, for example, in the case of forming a photoelectric conversion layer with a combination of conductivity types different from this embodiment, it is possible to use the first single crystal semiconductor layer 121 which is formed using a sliced n-type single crystal silicon substrate and the second single crystal semiconductor layer 122 which is formed in such a way that an impurity element to serve as a dopant is deposited.

Next, n-type and p-type impurity semiconductor layers are provided in the surface layer of the second single crystal semiconductor layer 122, and semiconductor junctions are formed. As an impurity element imparting n-type conductivity, phosphorus, arsenic, antimony, and the like, which are Group 15 elements in the periodic table, are typically given. As an impurity element imparting p-type conductivity, boron, aluminum, and the like, which are Group 13 elements in the periodic table, are typically given.

In this embodiment, the p-type first single crystal semiconductor layer 121 is formed in such a way that a p-type single crystal semiconductor substrate is sliced, and the i-type second single crystal semiconductor layer 122 is formed employing an epitaxial growth technique. In addition, semiconductor layers including the impurity element imparting n-type conductivity and semiconductor layers including the impurity element imparting p-type conductivity are formed in the surface layer of the second single crystal semiconductor layer 122. Here, n-type conductivity is imparted to the first impurity semiconductor layers 123a, 123c, and 123e, whereas p-type conductivity is imparted to the second impurity semiconductor layers 123b, 123d, and 123f. Therefore, the photoelectric conversion layer 120 of this embodiment has n-i-p (or p-i-n) junctions formed between the second single crystal semiconductor layer 122 and the first impurity semiconductor layers 123a, 123c, and 123e and the second impurity semiconductor layers 123b, 123d, and 123f.

Note that here, the impurity semiconductor layer of n-type conductivity and the impurity semiconductor layer of p-type conductivity are formed in the surface layer of the second single crystal semiconductor layer 122 in such a way that the impurities are scattered; however, the impurity semiconductor layers can be formed in such a way that the impurity semiconductor layers are deposited on the surface of the second single crystal semiconductor layer 122.

The first electrodes 144a, 144c, and 144e and the second electrodes 144b, 144d, and 144f which are used to extract current are provided over the first impurity semiconductor layers 123a, 123c, and 123e and the second impurity semiconductor layers 123b, 123d, and 123f, respectively. These electrodes are formed using a material including metal such as nickel, aluminum, silver, or solder. Specifically, these electrodes can be formed using a nickel paste, a silver paste, or the like employing a screen printing method.

A plurality of photoelectric conversion layers may be provided over the base substrate 110. A first connection electrode that connects the first electrode and the second electrode which are provided for one photoelectric conversion layer and for the other photoelectric conversion layer that is adjacent to the one photoelectric conversion layer, respectively, may be formed. A second connection electrode that connects the first electrodes and the second electrodes which are provided for the adjacent photoelectric conversion layers and for the adjacent photoelectric conversion layers, respectively, may be formed. Accordingly, a modular structure which can extract desired voltage and current can be formed.

Light emitted from the light-transmitting base substrate 110 side generates carriers in the first single crystal semiconductor layer 121 and the second single crystal semiconductor layer 122 which substantially serves as a light absorption layer. The carriers generated can move due to an internal electric field formed between the first impurity semiconductor layers 123a, 123c, and 123e and the second impurity semiconductor layers 123b, 123d, and 123f, and can be extracted as current from the first electrodes 144a, 144c, and 144e and the second electrodes 144b, 144d, and 144f. Simply the insulating layer 103 having a light-transmitting property is interposed between the light-transmitting base substrate 110 and the first single crystal semiconductor layer 121, so that a highly efficient photoelectric conversion device without a loss due to the shadow of a collection electrode can be manufactured.

As described above, a photoelectric conversion device according to this embodiment can save resources despite the use of a highly efficient single crystal semiconductor layer as a photoelectric conversion layer. Further, since the photoelectric conversion device has a back contact structure, a collection electrode is unnecessary on the photo acceptance surface side, and the highly efficient photoelectric conversion device without a shadow loss can be manufactured. In addition, since the photo acceptance surface is provided on the light-transmitting base substrate side, a module can be formed having a super-straight structure to which a highly efficient integration process which is similar to that of a thin film photoelectric conversion device can be used and which has high mechanical strength.

Note that this embodiment can be combined with any of the other embodiments, as appropriate.

### Embodiment 2

One embodiment of the present invention is a photoelectric conversion device having a single crystal semiconductor layer. A light-transmitting insulating substrate is used as a supporting substrate, semiconductor junctions and an electrode are formed on the surface side of the semiconductor layer, and a photo acceptance surface is provided on the supporting substrate side.

In this embodiment, a method for manufacturing a photoelectric conversion module will be described in details with reference to drawings.

Note that a photoelectric conversion module in this specification is a kind of photoelectric conversion device, and refers to a structure in which a plurality of photoelectric conversion layers is connected in series or in parallel in order to obtain desired power.

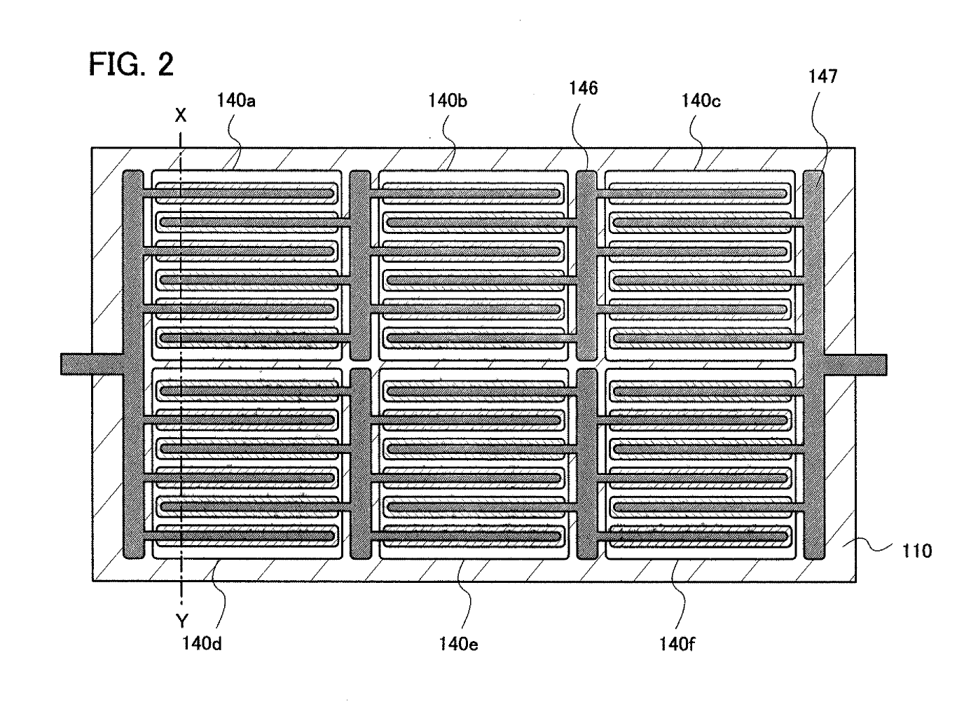

In FIG. 2, illustrated is an example in which a plurality of planar photoelectric conversion layers is arranged over one substrate having an insulating surface at predetermined intervals. Several photoelectric conversion layers are provided with electrodes and connected in series, which serves as an aggregate. The aggregates are connected in parallel, and a positive terminal and a negative terminal which extract power from the photoelectric conversion layers connected in series and in parallel are provided. Note that the number of photoelectric conversion layers provided over the substrate, an area of each photoelectric conversion layer, a method for connecting the photoelectric conversion layers, a method for extracting power from the photoelectric conversion module, and the like are optional, so that a practitioner may design them as appropriate in accordance with desired power, an installation site, or the like.

In this embodiment, an example in which photoelectric conversion layers 140a, 140b, 140c, 140d, 140e and 140f are arranged over the base substrate 110 at predetermined intervals is illustrated. Here, an example is illustrated in which the adjacent photoelectric conversion layers are electrically connected to each other, two aggregates in each of which three photoelectric conversion layers are connected in series are arranged, and the two aggregates of the photoelectric conversion layers are connected in parallel.

There are no particular limitations on the base substrate 110, and any substrate that can withstand a manufacturing process of a photoelectric conversion device according to one embodiment of the present invention and that has a light-transmitting property, for example, a light-transmitting insulating substrate can be used. Specifically, a quartz substrate, a ceramic substrate, a sapphire substrate, a variety of glass substrates used in the electronics industry such as, aluminosilicate glass, aluminoborosilicate glass, or barium borosilicate glass, and the like can be given as examples. A glass substrate, which can increase in area and is inexpensive, is preferably used because a cost reduction and productivity improvement can be achieved.

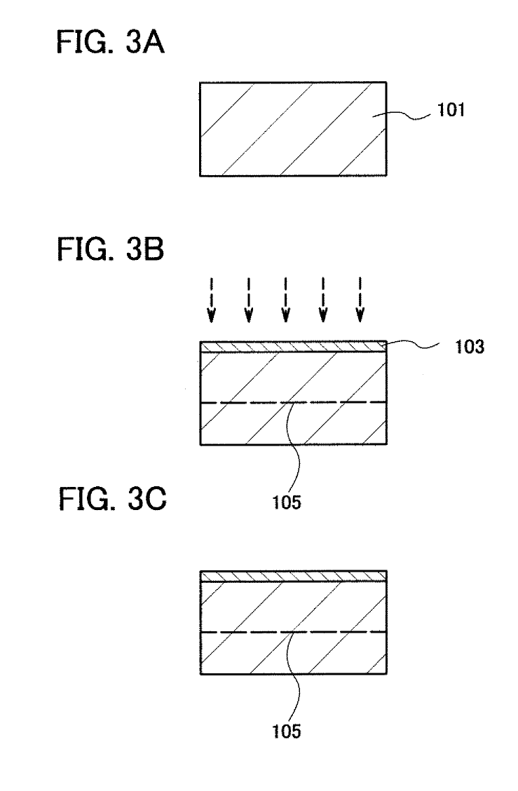

A single crystal semiconductor substrate 101 is prepared (see FIG. 3A).

As the single crystal semiconductor substrate 101, a single crystal silicon substrate is typically employed. Alternatively, a known single crystal semiconductor substrate can be used; for example, a single crystal germanium substrate, a single crystal silicon-germanium substrate, or the like can be used. As an alternative to the single crystal semiconductor substrate 101, a polycrystalline semiconductor substrate can be used; typically, a polycrystalline silicon substrate can be used. Therefore, in the case of using a polycrystalline semiconductor substrate instead of the single crystal semiconductor substrate, the “single crystal semiconductor” in the description below can be replaced with a “polycrystalline semiconductor”.

The single crystal semiconductor substrate 101 can be an n-type single crystal semiconductor substrate or a p-type single crystal semiconductor substrate. For example, the impurity concentration of a p-type single crystal semiconductor substrate is greater than or equal to approximately 1×10¹⁴ atoms/cm³ and less than or equal to approximately 1×10¹⁷ atoms/cm³, and the specific resistance thereof is greater than or equal to approximately 1×10⁻¹ Ω·cm and less than or equal to approximately 10 Ω·cm. In an example of this embodiment, a p-type single crystal semiconductor substrate is used as the single crystal semiconductor substrate 101.

The size (the area, the planar shape, the thickness, or the like) of the single crystal semiconductor substrate 101 may be determined by a practitioner in response to a specification of a manufacturing apparatus or a specification of a module. For example, as for the planar shape of the single crystal semiconductor substrate 101, a widely distributed circular substrate or a substrate processed into a desired shape can be used.

There are no particular limitations on planar shapes of the photoelectric conversion layers, and a rectangular shape including a square, a polygonal shape, or a circular shape can be employed. For example, the shape is a square of approximately 10 cm×10 cm.

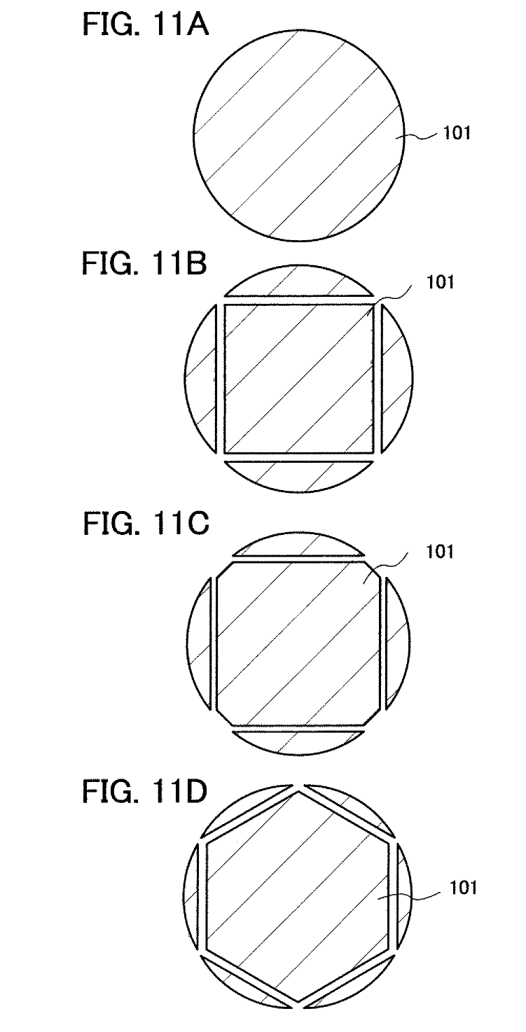

An example of processing the single crystal semiconductor substrate 101 will now be described. For example, the single crystal semiconductor substrate 101 illustrated in FIGS. 11A, 11B, 11C, and 11D can be used.

A circular single crystal semiconductor substrate 101 may be used without being cut as illustrated in FIG. 11A. Alternatively, a rectangular and substantially rectangular single crystal semiconductor substrates 101 may be used as illustrated in FIGS. 11B and 11C by being cut out from circular substrates.

FIG. 11B illustrates an example in which the rectangular single crystal semiconductor substrate 101 is cut out to have a rectangular shape of maximum size with its corners being in contact with the periphery of the circular single crystal semiconductor substrate 101. The angle at each corner of the single crystal semiconductor substrate 101 is approximately 90°.

FIG. 11C illustrates an example in which the single crystal semiconductor substrate 101 is cut out so that the distance between opposing lines is longer than that illustrated in FIG. 11B. The angle at each corner of the single crystal semiconductor substrate 101 is not 90°, and the single crystal semiconductor substrate 101 has a polygonal shape, not a rectangular shape.

Further alternatively, as illustrated in FIG. 11D, a hexagonal single crystal semiconductor substrate 101 may be cut out. FIG. 11D illustrates an example in which the hexagonal single crystal semiconductor substrate 101 is cut out to have a hexagonal shape of maximum size with its corners being in contact with the periphery of the circular single crystal semiconductor substrate 101. A hexagonal single crystal semiconductor substrate is cut out, whereby the amount of the cut edge of the substrate can be reduced more than the case of cutting out a rectangular single crystal semiconductor substrate.

Here is described the example in which a substrate with a desired shape is cut out from a circular single crystal semiconductor substrate. However, one embodiment of the present invention is not limited thereto, and a substrate with a desired shape may be cut out from a substrate with a shape other than a circular shape. A single crystal semiconductor substrate which is processed into a desired shape is easily used for a manufacturing apparatus which is used for a manufacture process of a photoelectric conversion device. When the photoelectric conversion module is formed, the photoelectric conversion layers can be easily connected to each other.

The single crystal semiconductor substrate 101 may have a thickness of a generally distributed substrate which conforms to the SEMI Standard, or may have a thickness which is adjusted as appropriate at the time of cutting out the single crystal semiconductor substrate 101 from an ingot. A thick single crystal semiconductor substrate is cut out from an ingot, so that a useless cutting margin can be reduced.

The single crystal semiconductor substrate 101 may have a large area. As for single crystal silicon substrates, substrates with a diameter of approximately 100 mm (4 inches), a diameter of approximately 150 mm (6 inches), a diameter of approximately 200 mm (8 inches), a diameter of approximately 300 mm (12 inches), and the like are widely distributed, and a large substrate with a diameter of approximately 400 mm (16 inches) has started to be distributed in recent years. Further, it is expected that a single crystal silicon substrate is increased to 16 inches or more in diameter in future, and it has already been expected that a substrate is increased to approximately 450 mm (18 inches) in diameter so that the substrate is used as a next-generation substrate. When the single crystal semiconductor substrate 101 with a large area is used, a plurality of photoelectric conversion layers can be formed from one substrate, and an area of spaces (non-electricity generation regions) which are generated by arrangement of a plurality of photoelectric conversion layers can be reduced, which can lead to improvement in productivity.

An embrittlement layer 105 is formed in a region at a predetermined depth from one surface of the single crystal semiconductor substrate 101 (see FIG. 3B).

The embrittlement layer 105 serves as a boundary at which the single crystal semiconductor substrate 101 is separated into a single crystal semiconductor layer and a separation substrate (a single crystal semiconductor substrate) in a separation process which is described later, and its vicinity. The depth at which the embrittlement layer 105 is to be formed is determined based on the thickness of the thin single crystal semiconductor layer which is formed later by the separation.

As a method for forming the embrittlement layer 105, an ion implantation method or an ion doping method, in each of which irradiation with ions accelerated by voltage is performed, a method utilizing multiphoton absorption, or the like can be used.

For example, the embrittlement layer 105 can be formed by introduction of hydrogen, helium and/or a halogen into the inside of the single crystal semiconductor substrate 101. In one example illustrated in FIG. 3B, one surface of the single crystal semiconductor substrate 101 is irradiated with ions accelerated by voltage to form the embrittlement layer 105 in a region at a predetermined depth of the single crystal semiconductor substrate 101. Specifically, the embrittlement layer 105 is formed in such a manner that the crystalline structure of a local region in the single crystal semiconductor substrate 101 is distorted to weaken the region by irradiation of the single crystal semiconductor substrate 101 with ions (typically, hydrogen ions) accelerated by voltage so that the ions or elements of the ions (hydrogen in the case of using hydrogen ions) are introduced into the single crystal semiconductor substrate 101.

In this specification, “ion implantation” refers to a method in which ions produced from a source gas are mass-separated and delivered to an object, so that elements of the ions are added to the object. Further, the term “ion doping” refers to a method in which ions produced from a source gas are delivered to an object without mass separation, so that elements of the ions are added to the object. The embrittlement layer 105 can be formed using an ion implantation apparatus with mass separation or an ion doping apparatus without mass separation.

The depth at which the embrittlement layer 105 is formed in the single crystal semiconductor substrate 101 (here, the depth from the irradiated surface or from the irradiated surface side of the single crystal semiconductor substrate 101 to the embrittlement layer 105 in a film thickness direction) can be controlled by acceleration voltage of ions for irradiation, a tilt angle (an inclination angle of the substrate), and/or the like. Therefore, in consideration of the desired thickness of the single crystal semiconductor layer after the slice, the voltage for accelerating the irradiation ions and/or the tilt angle is determined.

As the irradiation ions, the use of hydrogen ions generated from a source gas including hydrogen is preferable. When the single crystal semiconductor substrate 101 is irradiated with hydrogen ions, hydrogen is introduced thereto, so that the embrittlement layer 105 is formed in a region at a predetermined depth of the single crystal semiconductor substrate 101. For example, hydrogen plasma is generated from a source gas including hydrogen and the ions generated in the hydrogen plasma are accelerated by voltage and delivered; thus, the embrittlement layer 105 can be formed. Instead of hydrogen or in addition to hydrogen, ions generated from a source gas including a noble gas typified by helium or a halogen may be used to form the embrittlement layer 105. Note that the irradiation with particular ions is preferable because the region at the same depth in the single crystal semiconductor substrate 101 is weakened in a concentrated manner.

For example, the single crystal semiconductor substrate 101 is irradiated with ions generated from hydrogen, so that the embrittlement layer 105 is formed. By adjusting the acceleration voltage, the tilt angle, and the dosage of the irradiation ions, the embrittlement layer 105, which is the region doped with hydrogen at high concentration, can be formed at a predetermined depth of the single crystal semiconductor substrate 101. In the case of using the ions generated from hydrogen, the region which serves as the embrittlement layer 105 preferably includes hydrogen so that the peak value is greater than or equal to 1×10¹⁹ atoms/cm³ in terms of a hydrogen atom. The embrittlement layer 105, which is the region locally doped with hydrogen at high concentration, no longer has a crystalline structure but has a porous structure including microvoids. When heat treatment is performed at relatively low temperatures (approximately 700° C. or lower), there is a change in the volume of the microvoids in the embrittlement layer 105, so that the single crystal semiconductor substrate 101 can be separated at or near the embrittlement layer 105.

Note that a protective layer is preferably formed on the surface of the single crystal semiconductor substrate 101 which is irradiated with the ions, in order to prevent damage to the surface layer of the single crystal semiconductor substrate 101. In the example illustrated in FIG. 3B, the insulating layer 103 which can function as a protective layer is formed on at least one surface of the single crystal semiconductor substrate 101 and the surface of the substrate where the insulating layer is formed is irradiated with the ions accelerated by voltage. The insulating layer 103 is irradiated with the ions and the ions or elements of the ions that transmit through the insulating layer 103 are introduced to the single crystal semiconductor substrate 101. Thus, the embrittlement layer 105 is formed in a region at a predetermined depth of the single crystal semiconductor substrate 101.

The surface of the single crystal semiconductor substrate 101 preferably has an average surface roughness (Ra) of 0.5 nm or less, more preferably, 0.3 nm or less. Needless to say, the Ra is preferably smaller. When the planarity of the surface of the single crystal semiconductor substrate 101 is favorable, it is possible to favorably attach the single crystal semiconductor substrate 101 to the base substrate 110 later. Note that the average surface roughness (Ra) in this specification refers to centerline average roughness obtained by three-dimensional expansion of the centerline average roughness which is defined by JIS B0601 so as to correspond to a plane.

The insulating layer 103 which functions as a protective layer also functions as a bonding layer with the base substrate 110. However, the insulating layer 103 may be removed when planarity is lost in an ion irradiation process, and an insulating layer may be formed again (see FIG. 3C).

The insulating layer 103 can have a single-layer structure or a stacked structure of two or more layers. The surface (a bonding plane) to be attached to the base substrate 110 later and form a bonding preferably has good planarity, and more preferably has hydrophilicity. Specifically, when the insulating layer 103 is formed so that the average surface roughness (Ra) of the bonding plane is 0.5 nm or less, preferably, 0.3 nm or less, the attachment with the base substrate 110 can be performed favorably. Naturally, the smaller the average surface roughness (Ra) is, the more preferable it is.

For example, a layer that forms the bonding plane of the insulating layer 103 can be a silicon oxide layer, a silicon nitride layer, a silicon oxynitride layer, a silicon nitride oxide layer, or the like.

As for a layer which has a planar surface and which can form a hydrophilic surface, a thermally oxidized silicon layer or a silicon oxide layer formed employing a plasma enhanced CVD method using an organosilane gas is preferable. The bonding with the substrate can be strengthened by the use of such a silicon oxide layer. As an organosilane gas, a silicon-containing compound such as tetraethoxysilane (TEOS) (chemical formula: Si(OC₂H₅)₄), tetramethylsilane (TMS) (chemical formula: Si(CH₃)₄), tetramethylcyclotetrasiloxane (TMCTS), octamethylcyclotetrasiloxane (OMCTS), hexamethyldisilazane (HMDS), triethoxysilane (SiH(OC₂H₅)₃), or trisdimethylaminosilane (SiH(N(CH₃)₂)₃) can be used.

Further, for the layer which has a planar surface and which can form a hydrophilic surface, a layer of silicon oxide, silicon oxynitride, silicon nitride, or silicon nitride oxide which is formed employing a plasma enhanced CVD method using a silane-based gas such as silane, disilane, or trisilane can be used. For example, as the layer that forms the bonding plane of the insulating layer 103, a silicon nitride layer formed employing a plasma enhanced CVD method using silane and ammonia as a source gas can be used. Note that hydrogen may be added to the source gas including silane and ammonia; alternatively, nitrous oxide may be added to the source gas so that a silicon nitride oxide layer is formed. When at least one layer included in the insulating layer 103 is a silicon insulating layer including nitrogen, specifically a silicon nitride layer or a silicon nitride oxide layer, diffusion of impurities from the base substrate 110 which is later attached can be prevented.

Note that a silicon oxynitride layer is a layer that includes more oxygen than nitrogen. Specifically, in the case where measurements are performed using Rutherford backscattering spectrometry (RBS) and hydrogen forward scattering spectrometry (HFS), includes oxygen, nitrogen, silicon, and hydrogen at concentrations ranging from 50 atomic % to 70 atomic %, 0.5 atomic % to 15 atomic %, 25 atomic % to 35 atomic %, and 0.1 atomic % to 10 atomic %, respectively. Further, a silicon nitride oxide layer is a layer that includes more nitrogen than oxygen. Specifically, a silicon nitride oxide layer includes oxygen, nitrogen, silicon, and hydrogen at concentrations ranging from 5 atomic % to 30 atomic %, 20 atomic % to 55 atomic %, 25 atomic % to 35 atomic %, and 10 atomic % to 30 atomic %, respectively in the case where measurements are performed using RBS and HFS. Note that percentages of nitrogen, oxygen, silicon, and hydrogen fall within the ranges given above, where the total number of atoms included in the silicon oxynitride layer or the silicon nitride oxide layer is defined as 100 atomic %.

In any case, the insulating layer 103 is not limited to an insulating layer including silicon, as long as the insulating layer 103 has a planar bonding plane, specifically, the insulating layer 103 has a planar bonding plane with an average surface roughness (Ra) of 0.5 nm or less, preferably, 0.3 nm or less. Note that in the case where the insulating layer 103 has a stacked structure, the layers except the layer which forms the bonding plane are not limited thereto. In this embodiment, moreover, the insulating layer 103 needs to be formed at a temperature at which the embrittlement layer 105 formed in the single crystal semiconductor substrate 101 does not change, preferably at 350° C. or lower.

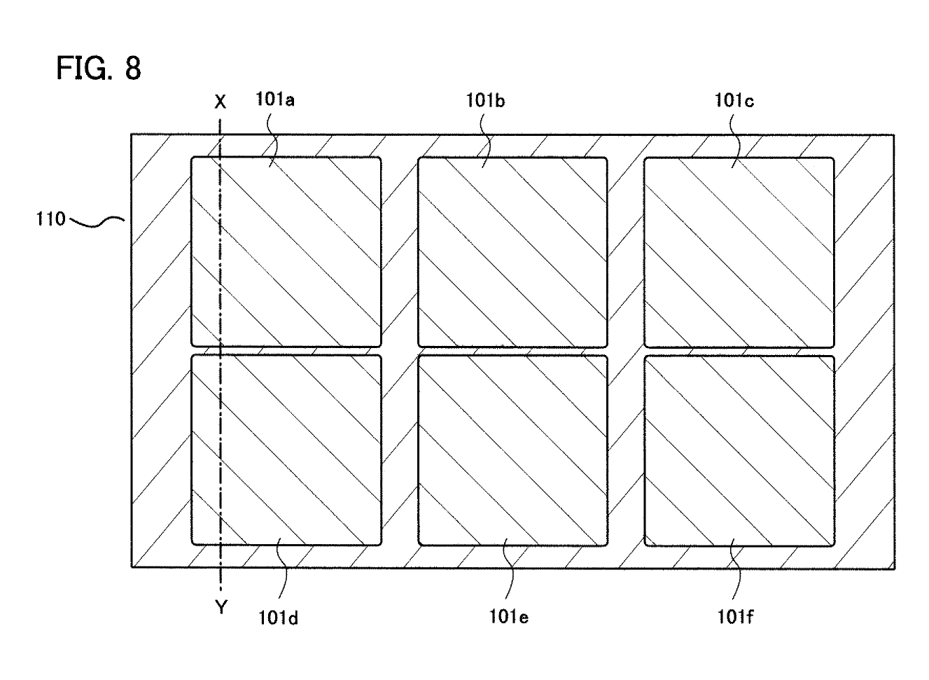

The embrittlement layer 105 is thus formed, and one surface side of the single crystal semiconductor substrate 101 provided with the insulating layer 103 and one surface side of the base substrate 110 are faced with, superposed on, and attached to each other. In one embodiment of the present invention, the photoelectric conversion module in which a plurality of photoelectric conversion layers is provided over one substrate is manufactured. Therefore, a plurality of single crystal semiconductor substrates 101 is attached to the base substrate 110 at predetermined intervals. FIG. 8 illustrates the case where six single crystal semiconductor substrates 101a to 101f are arranged over one base substrate 110 at predetermined intervals as an example.

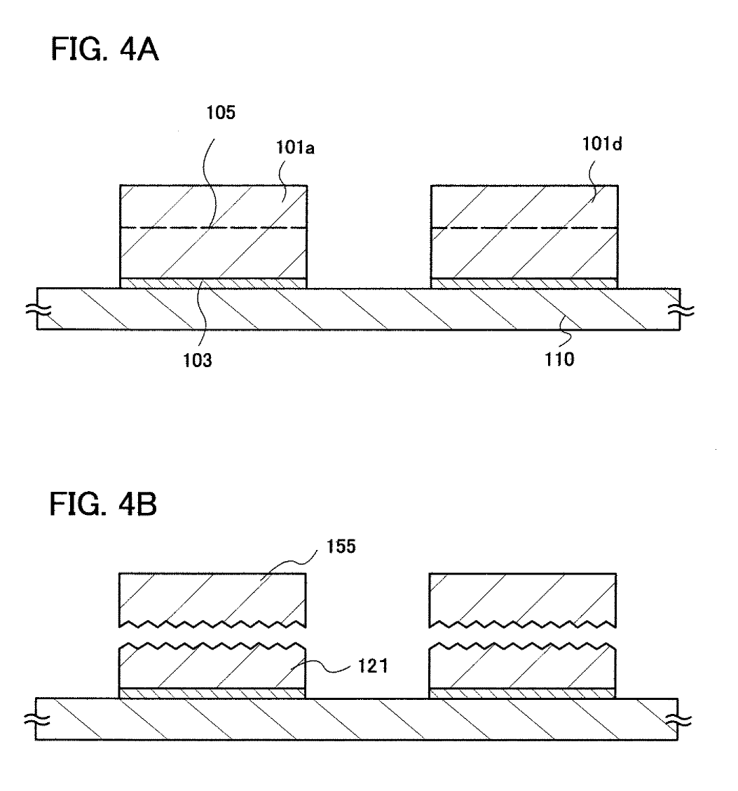

FIG. 4A corresponds to a cross section taken along the section line X-Y in FIG. 8, and the single crystal semiconductor substrates 101a and 101d attached to the base substrate 110 are illustrated. The interval between the adjacent single crystal semiconductor substrates (e.g., the single crystal semiconductor substrates 101a and 101d) is approximately 1 mm (see FIG. 4A and FIG. 8).

Note that cross-sectional views describing a manufacturing process in this specification illustrates the surface which corresponds to a cross section taken along the section line X-Y of FIG. 2 or the section line X-Y of FIG. 8.

The bonding plane of the single crystal semiconductor substrate 101 (the single crystal semiconductor substrates 101a to 101f) and the bonding plane of the base substrate 110 are brought into contact with each other and the bonding is formed by van der Waals forces or hydrogen bonding. For example, the base substrate 110 and each of the plurality of single crystal semiconductor substrates 101 which are superimposed are pressed at one place of the overlapped region, whereby van der Waals forces or hydrogen bonding can be spread to the entire area of the bonding planes. When one or both of the bonding planes have hydrophilic surfaces, hydroxyl groups or water molecules serve as an adhesive, and then water molecules diffuse in later heat treatment; then, the remaining composition forms silanol groups (Si—OH) and the bonding is formed by hydrogen bonding. Further, this bonding portion forms a siloxane bonding (O—Si—O) by release of hydrogen to form a covalent bond, whereby the bonding can be further strengthened.

The bonding plane of the single crystal semiconductor substrate 101 and the bonding plane of the base substrate 110 each preferably have an average surface roughness (Ra) of 0.5 nm or less, more preferably, 0.3 nm or less. Further, the sum of the average surface roughness (Ra) of the bonding plane of the single crystal semiconductor substrate 101 and the bonding plane of the base substrate 110 is 0.7 nm or less, preferably 0.6 nm or less, more preferably 0.4 nm or less. The bonding plane of the single crystal semiconductor substrate 101 and the bonding plane of the base substrate 110 each have a contact angle to pure water of 20° or less, preferably 10° or less, more preferably 5° or less. The total contact angle to pure water of the bonding plane of the single crystal semiconductor substrate 101 and the bonding plane of the base substrate 110 is 30° or less, preferably, 20° or less, more preferably, 10° or less. If the bonding planes are attached under the above conditions, they are attached in a favorable manner, whereby the bonding can be strengthened.

Note that before the single crystal semiconductor substrate 101 and the base substrate 110 are attached to each other, bonding planes of these are preferably subjected to surface treatment. The surface treatment can strengthen the bonding strength at an interface between the base substrate 110 and the single crystal semiconductor substrate 101.

As examples of the surface treatment, wet treatment, dry treatment, and combination of wet treatment and dry treatment can be given. Different wet treatment combination or different dry treatment combination may be used.

As examples of the wet treatment, ozone treatment using ozone water (ozone water cleaning), megasonic cleaning, two-fluid cleaning (method in which functional water such as pure water or hydrogenated water and a carrier gas such as nitrogen are sprayed together), and the like can be given. As examples of the dry treatment, ultraviolet treatment, ozone treatment, plasma treatment, plasma treatment with bias application, radical treatment, and the like can be given. Such surface treatment has an effect on the surface of the object to improve the hydrophilicity and cleanliness. As a result, the bonding strength between the substrates can be improved.

The wet treatment is effective for removal of macro dust and the like attached on the surface of the object; the dry treatment is effective for removal or decomposition of micro dust and the like such as an organic substance attached on the surface of the object. That is, when the dry treatment such as ultraviolet treatment is performed on the object and then the wet treatment such as cleaning is performed on the object, cleanliness and hydrophilicity of the surface of the object can be promoted. Further, generation of watermarks on the surface of the object can be suppressed.

As the dry treatment, it is preferable to perform surface treatment using ozone or oxygen in an active state such as singlet oxygen. Ozone or oxygen in an active state such as singlet oxygen enables organic substances attached on the surface of the object to be removed or decomposed effectively. Further, when surface treatment using ozone or oxygen in an active state such as singlet oxygen and using light having a wavelength less than 200 nm is performed, the organic substances attached on the surface of the object can be removed more effectively. Specific description thereof will be made below.

For example, irradiation with ultraviolet light under the atmosphere including oxygen is performed to perform the surface treatment of the object. Irradiation with light having a wavelength less than 200 nm and light having a wavelength greater than or equal to 200 nm under the atmosphere including oxygen may be performed, so that ozone and singlet oxygen can be generated. Alternatively, irradiation with light having a wavelength less than 180 nm may be performed, so that ozone and singlet oxygen can be generated.

Examples of reactions which occur by performing irradiation with light having a wavelength less than 200 nm and light having a wavelength greater than or equal to 200 nm in an atmosphere including oxygen are described.

O₂+hv(λ₁ nm)→O(³P)+O(³P) (1)

O(³P)+O₂→O₃ (2)

O₃+hv(λ₂ nm)→O(¹D)+O₂ (3)

First, irradiation with light (hv) having a wavelength (λ₁ nm) less than 200 nm in an atmosphere including oxygen (O₂) is performed to generate an oxygen atom (O(³P)) in a ground state (reaction formula (1)). Next, an oxygen atom (O(³P)) in a ground state and oxygen (O₂) are reacted with each other to generate ozone (O₃) (reaction formula (2)). Then, irradiation with light having a wavelength (λ₂ nm) greater than or equal to 200 nm in an atmosphere including the generated ozone (O₃) is performed to generate singlet oxygen O(¹D) in an excited state (reaction formula (3)). In an atmosphere including oxygen, irradiation with light having a wavelength less than 200 nm is performed to generate ozone while irradiation with light having a wavelength greater than or equal to 200 nm is performed to generate singlet oxygen by decomposing ozone. The above-described surface treatment can be performed by, for example, irradiation with a low-pressure mercury lamp (λ₁=185 nm, λ₂=254 nm) under the atmosphere including oxygen.

Example of reactions which occur by performing irradiation with light having a wavelength less than 180 nm under the atmosphere including oxygen are described below.

O₂+hv(λ₃ nm)→O(¹D)+O(³P) (4)

O(³P)+O₂→O₃ (5)

O₃+hv(λ₃ nm)→O(¹D)+O₂ (6)

First, irradiation with light having a wavelength (λ₃ nm) less than 180 nm in an atmosphere including oxygen (O₂) is performed to generate singlet oxygen O(¹D) in an excited state and an oxygen atom (O(³P)) in a ground state (reaction formula (4)). Next, an oxygen atom (O(³P)) in a ground state and oxygen (O₂) are reacted with each other to generate ozone (O₃) (reaction formula (5)). Then, irradiation with light having a wavelength (λ₃ nm) less than 180 nm in an atmosphere including the generated ozone (O₃) is performed to generate singlet oxygen in an excited state and oxygen (reaction formula (6)). In an atmosphere including oxygen, irradiation with light having a wavelength less than 180 nm among ultraviolet is performed to generate ozone and to generate singlet oxygen by decomposing ozone or oxygen. The above-described surface treatment can be performed by, for example, irradiation with a Xe excimer UV lamp under the atmosphere including oxygen.

Chemical bonds of an organic substance and the like bonded on the surface of an object are cut by the light having a wavelength less than 200 nm, and the organic substance can be oxidative-decomposed by ozone or singlet oxygen to be removed. With the above-described surface treatment, the hydrophilicity and cleanliness of the surface of the object can be improved, so that bonding can be favorably performed.

Note that the attachment may be performed after the bonding planes are irradiated with an atomic beam or an ionic beam or the bonding planes are subjected to plasma treatment or radical treatment. Through the above treatment, the bonding planes can be activated so that the attachment can be performed favorably. For example, the bonding plane can be activated by being irradiated with an inert gas neutral atomic beam of argon or an inert gas ion beam of argon or the like or activated by being exposed to oxygen plasma, nitrogen plasma, oxygen radicals, or nitrogen radicals. By the activation of the bonding planes, the bonding can be formed at low temperatures (e.g., 400° C. or lower) even between bases that include different materials, such as an insulating layer and a glass substrate. Further, a strong bonding can be formed when a bonding plane is processed with oxygen-added water, hydrogen-added water, pure water, or the like so that the bonding plane is made hydrophilic and the number of hydroxyls on the bonding plane is increased.

In this embodiment, a plurality of single crystal semiconductor substrates 101 is arranged on one base substrate 110. Although the single crystal semiconductor substrates may be arranged over the base substrate one by one, a plurality of single crystal semiconductor substrates can be arranged at one time when a holding means such as a tray is used, for example. More preferably, a desired number of single crystal semiconductor substrates are held by the holding means so as to be arranged over the base substrate at predetermined intervals, and arranged at one time. It is preferable that the shape or the like of the holding means is made correspondingly because the single crystal semiconductor substrate and the base substrate are easily aligned. Needless to say, the single crystal semiconductor substrates may be arranged over the base substrate while they are aligned one by one. The holding means of the single crystal semiconductor substrates may be a tray, a substrate for holding, a vacuum chuck, or an electrostatic chuck.

After the plurality of single crystal semiconductor substrates 101 and the base substrate 110 are superposed on each other, heat treatment and/or pressure treatment are/is preferably performed. Heat treatment and/or pressure treatment can increase the bonding strength. When the heat treatment is performed, the temperature of the heat treatment is set at less than or equal to the strain point of the base substrate 110 and at a temperature at which the volume of the embrittlement layer 105 formed in the single crystal semiconductor substrate 101 does not change, preferably at a temperature higher than or equal to 200° C. and lower than 410° C. The heat treatment is preferably performed in succession to a process in which the single crystal semiconductor substrate 101 and the base substrate 110 are superposed on each other. In the case of performing the pressure treatment, pressure is applied to the bonding planes in a perpendicular direction in consideration of the pressure resistance of the base substrate 110 and the single crystal semiconductor substrate 101. In succession to the heat treatment for increasing the bonding strength, another heat treatment for separating the single crystal semiconductor substrates 101 at the embrittlement layer 105, which is described later, may be performed.

Alternatively, when an insulating layer such as a silicon oxide layer, a silicon nitride layer, a silicon oxynitride layer, or a silicon nitride oxide layer may be formed on the base substrate 110 side, the base substrate 110 may be attached to the single crystal semiconductor substrate 101 with the insulating layer interposed therebetween. At this time, the insulating layer formed on the single crystal semiconductor substrate 101 can be attached to the base substrate 110.

Next, the single crystal semiconductor substrate 101 is separated at the embrittlement layer 105; thus, a sliced single crystal semiconductor layer is formed over the base substrate 110 (see FIG. 4B). As illustrated in FIG. 8, the single crystal semiconductor substrates 101a to 101f are arranged over one base substrate 110, and a plurality of stack bodies in which the insulating layer 103 and the first single crystal semiconductor layer 121 are sequentially stacked is formed over the base substrate 110, in accordance with the arrangement of the single crystal semiconductor substrates.

As in this embodiment, it is preferable to use heat treatment so as to separate the single crystal semiconductor substrate at the embrittlement layer 105. The heat treatment can be performed by a heat treatment apparatus such as rapid thermal annealing (RTA), furnace, an apparatus using dielectric heating with use of a high frequency wave such as a microwave or a millimeter wave generated in a high-frequency generator. As a heating method of the heat treatment apparatus, a resistance heating method, a lamp heating method, a gas heating method, an electromagnetic heating method, and the like can be given. Alternatively, laser beam irradiation or thermal plasma jet irradiation may be performed. An RTA apparatus can heat an object rapidly, and can heat the single crystal semiconductor substrate 101 up to approximately or a little higher temperature than the strain point of the single crystal semiconductor substrate 101 (or at a temperature approximately or at the strain point of the base substrate 110). The suitable temperature in the heat treatment for separating the single crystal semiconductor substrate 101 is higher than or equal to 410° C. and lower than the strain point of the single crystal semiconductor substrate 101 (and lower than the strain point of the base substrate 110). By the heat treatment performed at 410° C. or higher, there is a change in the volume of the microvoids formed in the embrittlement layer 105 so that the single crystal semiconductor substrate 101 can be separated at or near the embrittlement layer 105.

For example, the thickness of the first single crystal semiconductor layer 121 layer separated from the single crystal semiconductor substrate 101 can be greater than or equal to 20 nm and less than or equal to 1000 nm, preferably, greater than or equal to 40 nm and less than or equal to 300 nm. Naturally, a single crystal semiconductor layer having a thickness equal to or larger than the above thickness can be separated from the single crystal semiconductor substrate 101 by adjustment of the acceleration voltage or the like in forming the embrittlement layer.

The single crystal semiconductor substrate 101 is separated at the embrittlement layer 105, whereby the single crystal semiconductor layer is partly separated from the single crystal semiconductor substrate and the first single crystal semiconductor layer 121 is formed. Thus, a separation substrate 155, that is, the single crystal semiconductor substrate 101 from which the single crystal semiconductor layer is partly separated, is obtained. The separation substrate 155 can be reused repeatedly after being reprocessed. The separation substrate 155 may be reused as a single crystal semiconductor substrate for forming a photoelectric conversion device, or may be used for other purposes. By repeatedly reusing the separation substrate 155 as the single crystal semiconductor substrate which is used for one embodiment of the present invention, it is possible to manufacture a plurality of photoelectric conversion devices out of one material substrate.

Due to the separation of the single crystal semiconductor substrate 101 at the embrittlement layer 105, the separation plane of the sliced single crystal semiconductor layer (here, the first single crystal semiconductor layer 121) is uneven in some cases. Crystallinity and planarity of such an uneven surface are lost due to ion damage, and it is preferable that crystallinity and planarity of a surface be recovered so that the single crystal semiconductor layer is made to function as a seed layer when epitaxial growth is performed later. In order to recover crystallinity and remove a damaged layer, laser treatment or an etching process can be used, and planarity can be recovered at the same time.

Next, an example in which recovery of crystallinity and planarization can be performed using laser treatment will be described. In addition, as illustrated in FIG. 4B, an example in which the single crystal semiconductor substrates 101 are sliced and single crystal semiconductor layers (here, the first single crystal semiconductor layer 121) are arranged over the base substrate 110 at predetermined intervals will be described.

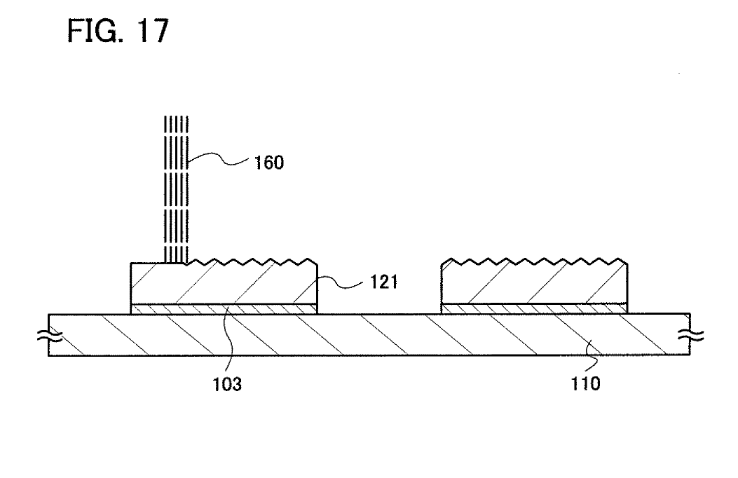

For example, as illustrated in FIG. 17, the single crystal semiconductor layer (here, the first single crystal semiconductor layer 121) formed over the base substrate 110 is irradiated with a laser beam 160 from the upper surface side of the single crystal semiconductor layer and the single crystal semiconductor layer is melted and solidified, whereby crystallinity and planarity of the single crystal semiconductor layer can be recovered.

Although the melting state of the single crystal semiconductor layer by irradiation with the laser beam 160 may be either partly-melted state or completely-melted state, the partly-melted state which is formed in such a way that only the upper layer (on the surface layer side) is melted to be a liquid phase is preferable. In the partly-melted state, a crystal can be grown using the solid phase portion of a single crystal as a seed. Note that in this specification, the completely-melted state means that the single crystal semiconductor layer is melted down to the vicinity of the lower interface of the single crystal semiconductor layer to be in a liquid phase state. The partly-melted state means that part (e.g., an upper portion) of the single crystal semiconductor layer is melted to be made in a liquid phase whereas another part (e.g., a lower portion) is kept in a solid phase without being melted.

As the laser beam 160 applicable to the laser treatment according to this embodiment, a laser beam having a wavelength that is absorbed by the single crystal semiconductor layer is employed. The wavelength of a laser beam can be determined in consideration of the skin depth of the laser beam, or the like. For example, light having an emission wavelength in the range from ultraviolet region to visible light region is selected; typically, light having a wavelength in the range from 250 nm to 700 nm can be used. As a typical example of the laser beam 160, a solid-state laser typified by a YAG laser or a YVO₄ laser, or an excimer laser (XeCl (308 nm), KrF (248 nm) is used. In the case of using the solid-state laser, a second harmonic (532 nm), a third harmonic (355 nm), or a fourth harmonic (266 nm) is used. As the laser that emits the laser beam 160, a continuous wave laser, a quasi continuous wave laser, or a pulsed laser can be used. In order to form the partly-melted state, it is preferable to use a pulsed laser which can emit a laser beam having a repetition rate of less than or equal to 1 MHz and a pulse width of greater than or equal to 10 nanosecond and less than or equal to 500 nanosecond. As a laser, a XeCl excimer laser with a repetition rate of greater than or equal to 10 Hz and less than or equal to 300 Hz, a pulse width of approximately 25 nanoseconds, and a wavelength of 308 nm can be used, for example.

Further, the energy of the laser beam for irradiation of the single crystal semiconductor layer is determined based on the wavelength of the laser beam, the skin depth of the laser beam, and the thickness of the single crystal semiconductor layer as the object to be treated. The energy of the laser beam can be, for example, in the range of from 300 mJ/cm² to 800 mJ/cm² inclusive. For example, the energy density of the laser beam can be greater than or equal to 600 mJ/cm² and less than or equal to 700 mJ/cm² in the case where the thickness of the single crystal semiconductor layer is approximately 120 nm, a pulsed laser is used as the laser, and a wavelength of the laser beam is 308 nm.

Irradiation with the laser beam 160 is preferably performed in an inert gas atmosphere such as a noble gas atmosphere or a nitrogen atmosphere or in a vacuum state. Irradiation with the laser beam 160 in an inert atmosphere or a vacuum state can suppress generation of cracks in the single crystal semiconductor layer as the object to be treated more than the irradiation with a laser beam in an air atmosphere. For example, when irradiation with the laser beam 160 is conducted in an inert gas atmosphere, the atmosphere in an airtight chamber is controlled to be an inert gas atmosphere for irradiation with the laser beam 160. When the chamber is not used, by blowing an inert gas such as a nitrogen gas to the surface irradiated with the laser beam 160 (the surface of the first single crystal semiconductor layer 121 in FIG. 17), irradiation with the laser beam 160 in the inert gas atmosphere can be substantially realized.

The laser beam 160 preferably has a linear form on an irradiation surface with homogenous energy distribution using an optical system. By adjusting the form of the laser beam 160 with use of an optical system, the surface can be irradiated uniformly with high throughput. When the beam length of the laser beam 160 can be made longer than one side of the base substrate 110, all of the single crystal semiconductor layers formed over the base substrate 110 can be irradiated with the laser beam 160 at one scanning. In the case where the beam length of the laser beam 160 is shorter than one side of the base substrate 110, all the single crystal semiconductor layers formed over the base substrate 110 can be irradiated with the laser beam 160, by performing scanning plural times.

Moreover, heat treatment can be conducted in combination with the laser processing, which can lead to recovery of crystallinity or damage repairing efficiently. The heat treatment is preferably conducted at higher temperature and/or a longer time using a heating furnace, RTA, or the like than a heat treatment for separating the single crystal semiconductor substrate 101 at the embrittlement layer 105. Needless to say, the heat treatment is conducted at a temperature that is not above the strain point of the base substrate 110.

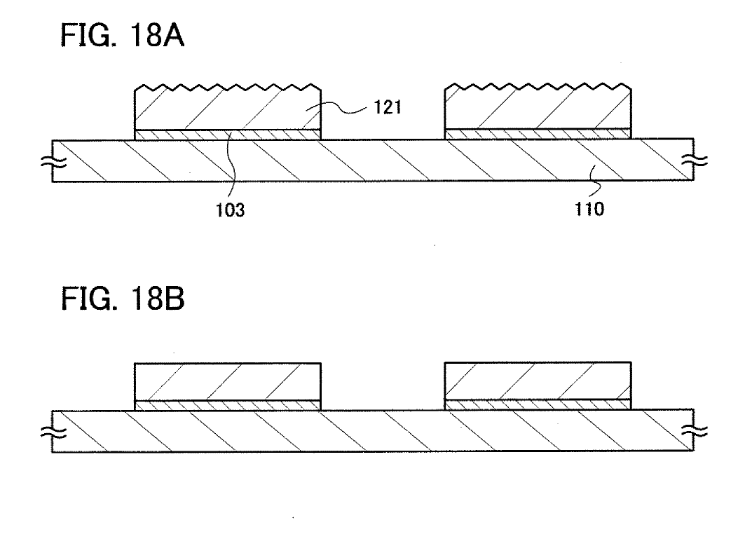

Instead of laser treatment, a means which is used to remove a damaged layer employing etching may also be used. In this case, the first single crystal semiconductor layer 121 is made thin as illustrated in FIG. 18B.

By etching the single crystal semiconductor layer from the surface layer, which is formed by being sliced from the single crystal semiconductor substrate, damaged portions due to the formation of the embrittlement layer or separation of the single crystal semiconductor substrate can be removed, and the surface layer of the single crystal semiconductor substrate can be planarized. Here, an example is described in which such a surface layer of the first single crystal semiconductor layer 121 as illustrated in FIG. 18A is etched, in order that the damaged portions due to the formation of the embrittlement layer or separation of the single crystal semiconductor substrate are removed.

The thickness by which the single crystal semiconductor layer is made thin (the thickness of the etched layer) can be set by a practitioner, as appropriate. For example, the single crystal semiconductor substrate is sliced to form an approximately 300-nm-thick single crystal semiconductor layer, and then a portion with a thickness of approximately 200 nm of the single crystal semiconductor layer is etched from its surface layer, whereby an approximately 100-nm-thick single crystal semiconductor layer whose damaged portion is removed is formed.

The thinning of the single crystal semiconductor layer (here, the first single crystal semiconductor layer 121) can be conducted by dry etching or wet etching, preferably, dry etching can be used.

For example, the dry etching may be performed by a dry etching method, for example, an RIE (reactive ion etching) method, an ICP (inductively coupled plasma) etching method, an ECR (electron cyclotron resonance) etching method, a parallel plate (capacitive coupled type) etching method, a magnetron plasma etching method, a dual-frequency plasma etching method, a helicon wave plasma etching method, or the like. As the etching gas, for example, a chlorine-based gas such as chlorine, boron chloride, or silicon chloride (including silicon tetrachloride), a fluorine-based gas such as trifluoromethane, carbon fluoride, nitrogen fluoride, or sulfur fluoride, a bromide-based gas such as hydrogen bromide, and the like can be given. Additionally, an inert gas such as helium, argon, or xenon; an oxygen gas; a hydrogen gas; and the like can be given.

Note that, after the single crystal semiconductor is made thin as illustrated in FIG. 18B, the single crystal semiconductor layer is irradiated with a laser beam so that crystallinity of the single crystal semiconductor layer can be further improved.

The crystallinity of the single crystal semiconductor layer formed being sliced from the single crystal semiconductor substrate is reduced due to the formation of the embrittlement layer or separation of the single crystal semiconductor substrate. Thus, by the laser beam irradiation or the etching as described above, the crystallinity on the surface of the first single crystal semiconductor layer 121 can be recovered. The single crystal semiconductor layer can function as a seed layer in epitaxial growth, and thus the crystallinity of the semiconductor layer formed by the epitaxial growth can be improved by the improvement in the crystallinity of the single crystal semiconductor layer.

The first single crystal semiconductor layer 121 whose crystallinity is recovered is used as a seed layer when the second single crystal semiconductor layer 122 to substantially serve as a light absorption layer is grown. Alternatively, a polycrystalline semiconductor substrate (typically, a polycrystalline silicon substrate) can be used instead of the single crystal semiconductor substrate. In this case, a polycrystalline semiconductor layer (typically, a polycrystalline silicon layer) is formed as the first single crystal semiconductor layer 121.

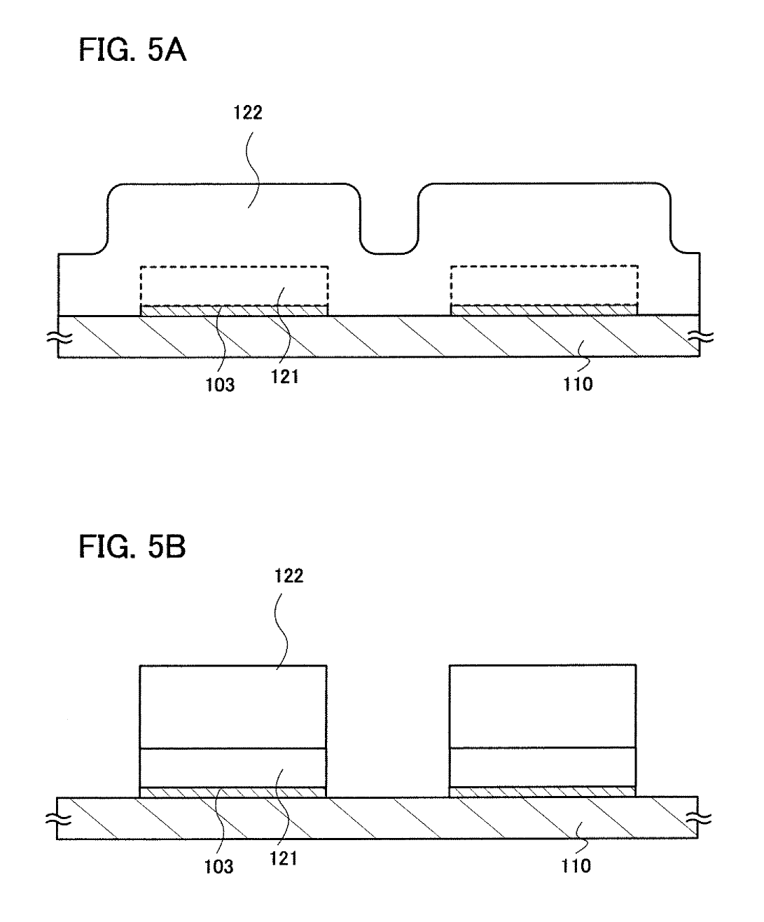

Next, the second single crystal semiconductor layer 122 is formed over the first single crystal semiconductor layer 121 (see FIG. 5A). A single crystal semiconductor layer having a desired thickness may be separated from a single crystal semiconductor substrate by slicing, but the thickness of the single crystal semiconductor layer is preferably increased using an epitaxial growth method such as solid phase epitaxy or vapor phase epitaxy.

In the case of slicing a single crystal semiconductor substrate by an ion implantation method or an ion doping method, acceleration voltage should be increased in order to make the single crystal semiconductor layer which is to be separated thick. However, increase in the acceleration voltage of an ion implantation apparatus or an ion doping apparatus has limitation based on the aspect of the apparatus, or radiation rays which are safety hazard might be generated due to increase of the acceleration voltage. Further, in the case of a conventional apparatus, since it is difficult to perform irradiation with a large amount of ions with the acceleration voltage increased, a long period of time is necessary for obtaining a predetermined amount of ions implanted, which results in longer takt time.

The above safety hazard can be avoided by employing an epitaxial growth method. Further, the single crystal semiconductor substrate as a source material can be left thick, and the number of reusing it is increased, which leads to resource saving.

Since single crystal silicon as a typical example of a single crystal semiconductor is an indirect transition semiconductor, its light absorption coefficient is lower than that of direct transition amorphous silicon. Accordingly, single crystal silicon is preferably at least several times or more times as thick as amorphous silicon in order to absorb sufficient solar light. Here, the total thickness of the first single crystal semiconductor layer 121 and the second single crystal semiconductor layer 122 is greater than or equal to 5 μm and less than or equal to 200 μm, preferably greater than or equal to 10 μm and less than or equal to 100 μm.

A method for forming the second single crystal semiconductor layer will be described. First, a non-single-crystal semiconductor layer is formed entirely over the substrate so as to cover the plurality of stack bodies and the space between adjacent stacked bodies. The plurality of stack bodies is arranged over the base substrate 110 at predetermined intervals, and the non-single-crystal semiconductor layer is formed so as to cover the plurality of stacked bodies. When heat treatment is performed, the non-single-crystal semiconductor layer is subjected to a solid phase epitaxial growth with the use of the first single crystal semiconductor layer as a seed layer, resulting in the second single crystal semiconductor layer 122 being formed.

The non-single-crystal semiconductor layer is formed by a chemical vapor deposition method typified by a plasma enhanced CVD method. With the use of a plasma enhanced CVD method, a microcrystal semiconductor or an amorphous semiconductor can be formed by changing deposition conditions such as the flow rate of the gases and applied power. For example, the flow rate of the dilution gas (e.g., hydrogen) to a semiconductor source gas (e.g., silane) is from 10:1 to 2000:1, preferably from 50:1 to 200:1 so that a microcrystal semiconductor layer (typically, a microcrystal silicon layer) can be formed. The flow rate of the dilution gas to the semiconductor source gas is less than 10 times (less than 10:1) so that an amorphous semiconductor layer (typically, an amorphous silicon layer) can be formed. In addition, by mixing a doping gas into a reaction gas, an n-type or p-type non-single-crystal semiconductor layer is formed and solid phase grown so that an n-type or p-type single crystal semiconductor layer can be formed.

Heat treatment for solid phase growth can be conducted with the above-described heat treatment apparatus such as RTA, a furnace, or a high-frequency generator. When the RTA apparatus is used, it is preferable that the process temperature be higher than or equal to 500° C. and lower than or equal to 750° C. and the process time be longer than or equal to 0.5 minute and shorter than or equal to 10 minutes. When a furnace is used, it is preferable that the process temperature be higher than or equal to 500° C. and lower than or equal to 650° C. and the process time be longer than or equal to 1 hour and shorter than or equal to 4 hours.

The second single crystal semiconductor layer 122 using the first single crystal semiconductor layer 121 as a seed layer can be formed using gas phase epitaxial growth employing a plasma enhanced CVD method.

The conditions of a plasma enhanced CVD method for promoting the vapor phase epitaxial growth depend on the flow rates of gases included in a reaction gas, power to be applied, or the like. For example, in an atmosphere including a semiconductor source gas (silane) and a dilution gas (hydrogen), the flow rate of the dilution gas to the semiconductor source gas is 6 or more:1, preferably 50 or more:1, so that the second single crystal semiconductor layer 122 can be formed. By mixing a doping gas into the reaction gas, an n-type or p-type single crystal semiconductor layer can be formed by vapor phase growth. The flow rate of the dilution gas may be changed during the process of forming the second single crystal semiconductor layer 122. For example, just after the formation started, a thin semiconductor layer is formed at the flow rate of hydrogen to silane: approximately 150:1, and then a thick semiconductor layer is formed at the flow rate of hydrogen to silane: approximately 6:1, so that the second single crystal semiconductor layer 122 can be formed. Just after the formation started, a thin semiconductor layer is formed under a condition where the semiconductor source gas is diluted by the dilution gas at a high dilution ratio, and then a thick semiconductor layer is formed under a condition where the semiconductor source gas is diluted by the dilution gas at a low dilution ratio, so that film peeling can be prevented and the deposition rate can be increased for vapor phase growth.

A plurality of stack bodies (the insulating layer 103 and the first single crystal semiconductor layers 121) is arranged over the base substrate 110 at predetermined intervals, and no seed layer exists between the adjacent stacked bodies. The crystal of the second single crystal semiconductor layer 122 of this embodiment may be grown at least over the stacked bodies (the insulating layer 103 and the first single crystal semiconductor layer 121), and the crystal state of the semiconductor layer formed between the adjacent stacked bodies is not particularly limited.

Although there is no limitation on the conductivity type of the first single crystal semiconductor layer 121, a single crystal semiconductor layer which is formed using a sliced p-type single crystal silicon substrate is used. Although there is no limitation on the conductivity type of the second single crystal semiconductor layer 122, an i-type single crystal semiconductor layer is used here. Note that to form a photoelectric conversion layer with a combination of different conductivity types from this embodiment, there are a method in which base materials having different conductivity types are used when the first single crystal semiconductor layer 121 is formed, and a method in which impurity elements imparting different conductivity types are introduced when the second single crystal semiconductor layer 122 is formed.

The semiconductor layer formed between the adjacent stack bodies makes the adjacent stack bodies unified and hinders later integration; therefore, the adjacent stack bodies are separated into a plurality of stack bodies again (see FIG. 5B).

A separation can be performed using a laser irradiation method or an etching method, and the same means used in the aforementioned recovery of crystallinity on the surface of the first single crystal semiconductor layer 121 can be used. In the case of laser irradiation, processing is performed in such a way that the energy density is set higher and the space between the adjacent stack bodies is irradiated. In the case of etching, processing is performed in such a way that a protective layer which protects the stack bodies is formed only above the stack bodies, and then etching time is set longer. Note that the entire semiconductor layer formed between the adjacent stack bodies is not necessarily removed, and the stack bodies may be separated in an electrically high resistance state.

Next, the surface layer of the second single crystal semiconductor layer 122 is provided with diffusion regions of impurities to serve as an n-type semiconductor and a p-type semiconductor, and semiconductor junctions are formed. As the impurity element imparting n-type conductivity, phosphorus, arsenic, antimony, and the like, which are Group 15 elements of the periodic table, are typically given. As the impurity element imparting p-type conductivity, boron, aluminum, and the like, which are Group 13 elements of the periodic table, are typically given.

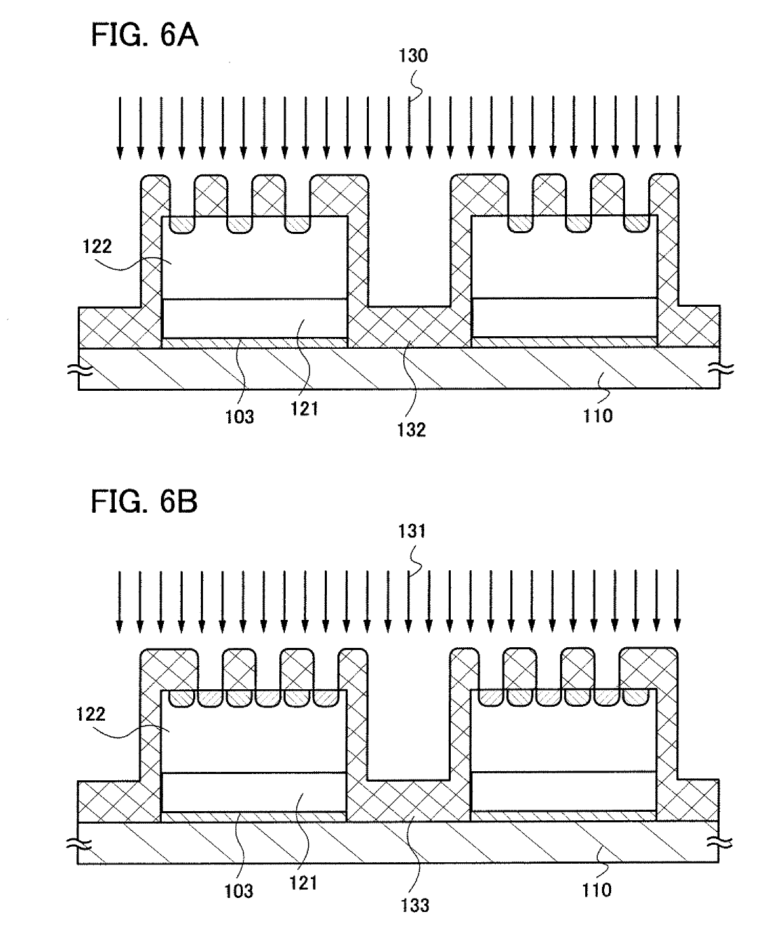

A photoresist 132 having openings for forming the first impurity semiconductor layer is provided as a protective layer over the second single crystal semiconductor layer 122, and a phosphorus ion 130 which imparts n-type conductivity is introduced employing an ion doping method or an ion implantation method. The photoresist 132 is removed, and then a photoresist 133 having openings for forming the second impurity semiconductor layer is provided as a protective layer again, and a boron ion 131 which imparts p-type conductivity is introduced employing an ion doping method or an ion implantation method (see FIGS. 6A and 6B).

For example, an ion doping apparatus by which generated ions are accelerated by voltage without mass separation and the substrate is irradiated with ions is used, and the phosphorus ion 130 is introduced using phosphine as a source gas. Here, hydrogen or helium may be added to phosphine which is used as a source gas. With use of an ion doping apparatus, the area to be irradiated with the ion beam can be enlarged, and treatment can be efficiently performed. For example, a linear ion beam whose length exceeds one side of the base substrate 110 is formed and delivered from one end to the other end of the base substrate 110; thus, an impurity can be introduced to the surface layer of the second single crystal semiconductor layer 122 at a uniform depth.

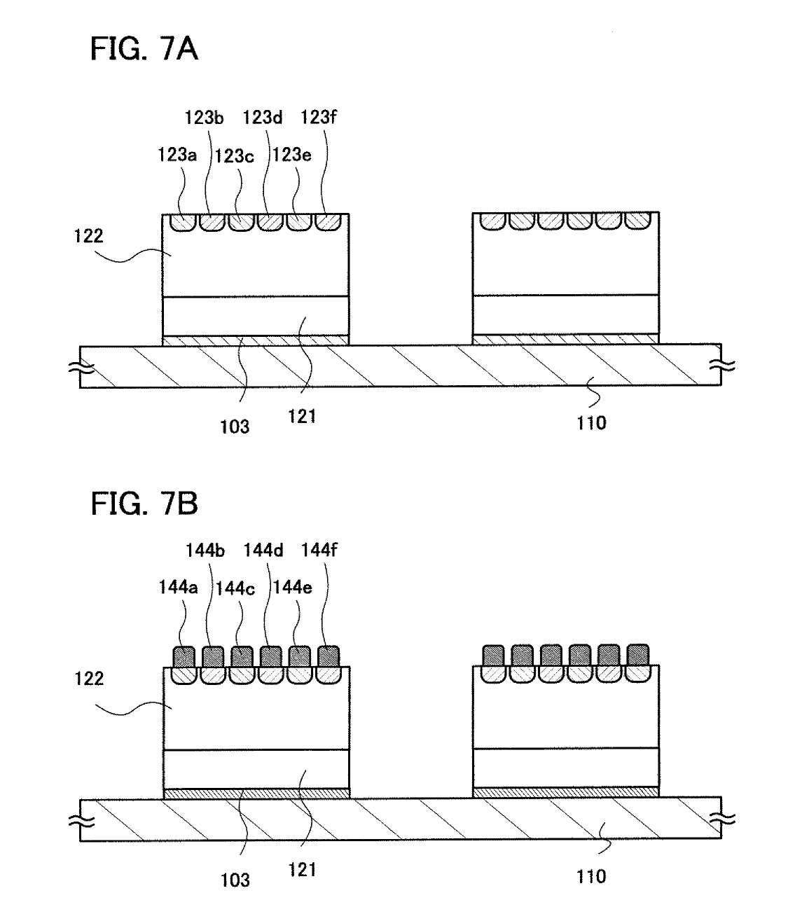

Next, a region to which the impurities are introduced in a state illustrated in FIG. 7A is activated. The activation is performed using heat treatment or laser irradiation, so that the crystallinity of a region which is damaged due to introduction of the impurities is recovered, a combination of an impurity atom and a semiconductor atom is formed, and conductivity is provided.

For a heat treatment method, the same method can be employed in which the single crystal semiconductor substrate 101 provided with the embrittlement layer 105 is attached to the base substrate 110 and separated at the embrittlement layer 105. In the case of laser irradiation, a method which can be used for the aforementioned recovery of crystallinity on the surface of the first single crystal semiconductor layer 121 can be employed.

In this embodiment, the single crystal semiconductor substrate is sliced to form the first single crystal semiconductor layer 121, and the i-type second single crystal semiconductor layer 122 is formed employing an epitaxial growth technique using the first single crystal semiconductor layer 121 as a seed layer. In addition, semiconductor layers including the impurity element imparting n-type conductivity and semiconductor layers including the impurity element imparting p-type conductivity are formed in the surface layer of the second single crystal semiconductor layer 122. Here, n-type conductivity is imparted to the first impurity semiconductor layers 123a, 123c, and 123e, whereas p-type conductivity is imparted to the second impurity semiconductor layers 123b, 123d, and 123f. As a result, the photoelectric conversion layer 120 of this embodiment has n-i-p (or p-i-n) junctions formed between the second single crystal semiconductor layer 122, the first impurity semiconductor layers 123a, 123c, and 123e, and the second impurity semiconductor layers 123b, 123d, and 123f.

The first electrodes 144a, 144c, and 144e which serve as negative electrodes are provided over the first impurity semiconductor layers 123a, 123c, and 123e formed with activation, respectively. Similarly, the second electrodes 144b, 144d, and 144f which serve as positive electrodes are provided over the second impurity semiconductor layers 123b, 123d, and 123f formed with activation, respectively. These electrodes are formed using a material including metal such as nickel, aluminum, silver, or lead-tin (solder). Specifically, these electrodes can be formed using a nickel paste, a silver paste, or the like employing a screen printing method (see FIG. 7B).

A first connection electrode 146 which connects adjacent photoelectric conversion layers in series and a second connection electrode 147 which connects adjacent photoelectric conversion layers in parallel are formed using the same layer as that of the first electrodes 144a, 144c, and 144e and the second electrodes 144b, 144d, and 144f (see FIG. 2). Here, although these electrodes formed in individual photoelectric conversion layers and these connection electrodes are formed as a unity, different names are given to these for convenience. Needleless to say, the connection electrode can be formed with a different layer from these electrodes.

From the above, the first single crystal semiconductor layer is used as a seed layer and the second single crystal semiconductor layer is epitaxially grown over the base substrate, and a plurality of the photoelectric conversion layers which is formed in such a manner that semiconductor junctions are provided in the surface layer of the second single crystal semiconductor layer is integrated, resulting in the photoelectric conversion module being formed.

The photoelectric conversion layer is formed using the single crystal semiconductor layer which is directly bonded to the base substrate with the insulating layer interposed therebetween without an adhesive; therefore, the photoelectric conversion module having high mechanical strength in addition to improvement in conversion efficiency can be provided.

In this embodiment, an example in which the first impurity semiconductor layers 123a, 123e, and 123e serve as n-type semiconductors, and the second impurity semiconductor layers 123b, 123d, and 123f serve as p-type semiconductors is described; naturally, the n-type semiconductors and the p-type semiconductors can be replaced with each other.

In this embodiment, an example in which the second single crystal semiconductor layer 122 which is epitaxially grown is provided with an i-type conductivity and the p-i-n junctions are formed is described; however, the second single crystal semiconductor layer 122 can be provided with n-type or p-type conductivity and p-n junctions can be formed. At this time, it is preferable that an impurity semiconductor layer having the same conductivity type as that of the second single crystal semiconductor layer 122 be formed using a layer including a dopant at high concentration.

Note that this embodiment can be combined with any of the other embodiments, as appropriate.

### Embodiment 3

In this embodiment, an example of a method for manufacturing a photoelectric conversion device, which is different from that described in Embodiment 2, will be described. Note that the description of a portion which overlaps with the above embodiments is omitted or partially simplified.

As illustrated in FIG. 5B, stack bodies formed using the insulating layer 103, the first single crystal semiconductor layer 121, and the second single crystal semiconductor layer 122 are formed over the base substrate 110 in accordance with Embodiment 2.

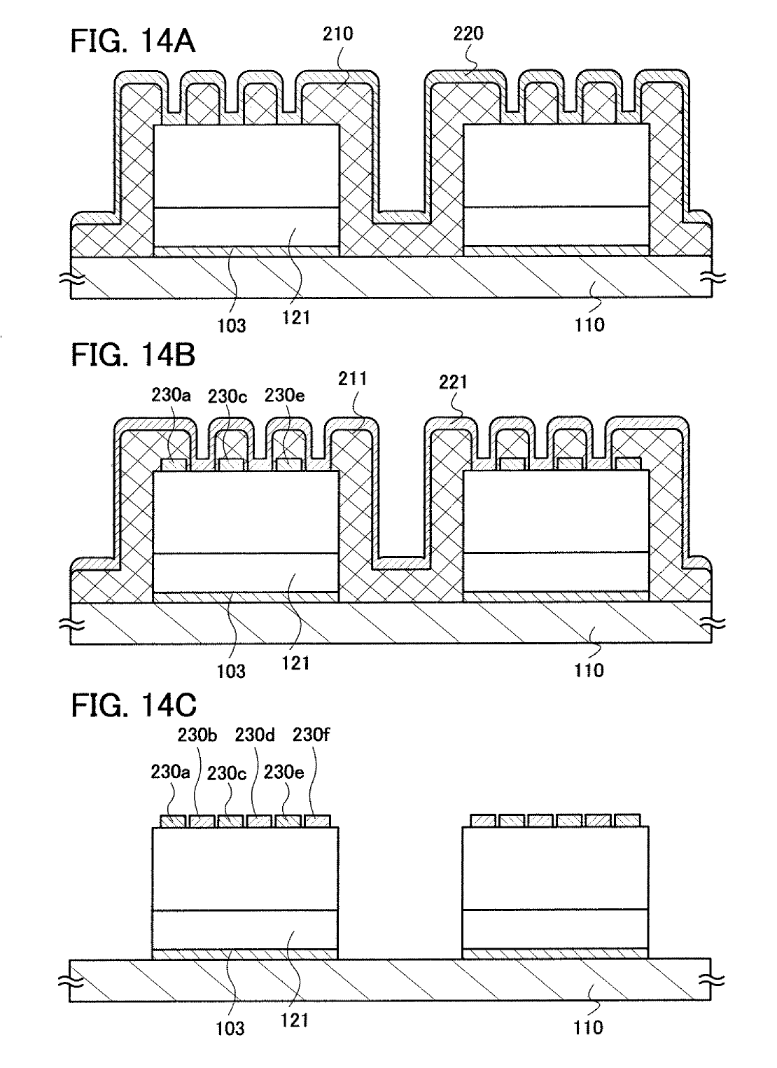

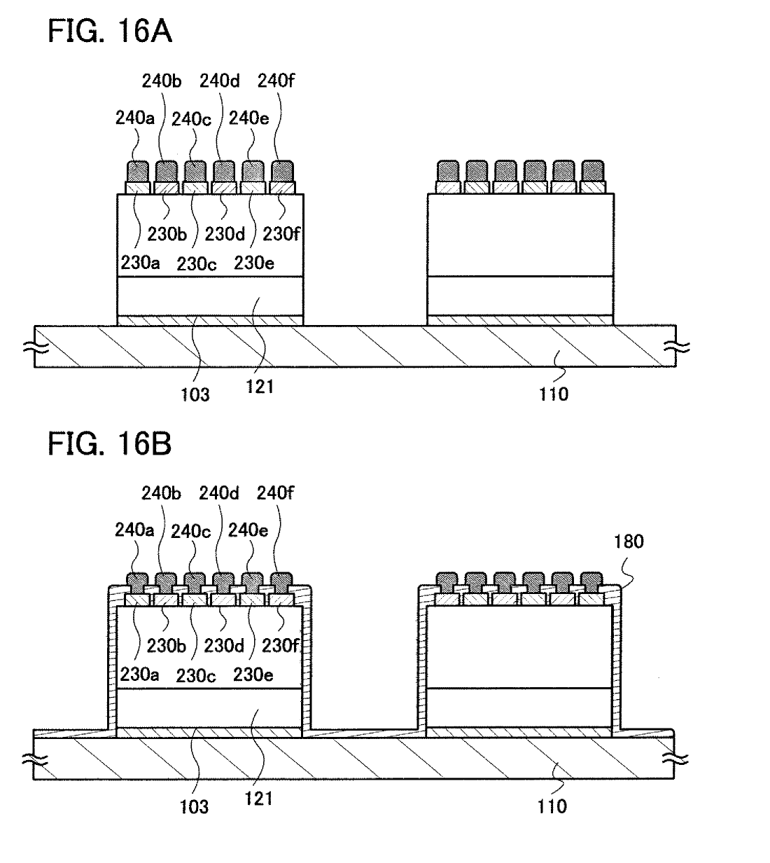

Over the stack bodies, first impurity semiconductor layers 230a, 230c, and 230e and second impurity semiconductor layers 230b, 230d, and 230f are alternately formed in a band shape with no overlap. Over the impurity semiconductor layers, first electrodes 240a, 240c, and 240e and second electrodes 240b, 240d, and 240f are formed, so that the photoelectric conversion device can be completed (see FIGS. 14A, 14B, and 14C and FIG. 16A).

In a bulk photoelectric conversion device, an impurity semiconductor layer having one conductivity type is formed in a bulk having a conductivity type which is opposite to the one conductivity type of the impurity semiconductor layer, and an internal electric field which is needed for transfer of carriers is formed in a depletion layer generated at a p-n junction interface. On the other hand, the impurity semiconductor layers can be formed in a manner similar to that of a thin film photoelectric conversion device, and p-n junctions or p-i-n junctions are formed, so that an internal electric field can be formed between a p-type semiconductor layer and an n-type semiconductor layer.

A specific example of a manufacturing method will be described. A structure illustrated in FIG. 5B is formed, and a photoresist 210 having band-shaped openings at predetermined intervals is formed over the second single crystal semiconductor layer 122; further, a first impurity semiconductor layer 220 is formed on the entire surface thereof (see FIG. 14A). An unnecessary film is removed employing a lift-off method; then, the first impurity semiconductor layers 230a, 230c, and 230e are formed, and a photoresist 211 having band-shaped openings which are different from those provided for the photoresist 210 is formed over the second single crystal semiconductor layer 122 provided with the first impurity semiconductor layers 230a, 230c, and 230e. The second impurity semiconductor layer 221 is formed on the entire surface over the photoresist 211 (see FIG. 14B). An unnecessary film is removed again employing a lift-off method, and a structure in which the first impurity semiconductor layers 230a, 230c, and 230e and the second impurity semiconductor layers 230b, 230d, and 230f are alternately formed in a band shape over the stack bodies with no overlap is obtained (see FIG. 14C). Lastly, the first electrodes 240a, 240c, and 240e and the second electrodes 240b, 240d, and 240f are formed, whereby the photoelectric conversion device is completed (see FIG. 16A).

In this embodiment, the second single crystal semiconductor layer 122 is formed to have i-type conductivity. For the first impurity semiconductor layer 220, a non-single-crystal semiconductor layer is formed using silane and phosphine including an impurity element imparting n-type conductivity (e.g., phosphorus) for a source gas employing a plasma enhanced CVD method. In addition, for a second impurity semiconductor layer 221, a non-single-crystal semiconductor layer is formed using silane and diborane including an impurity element imparting p-type conductivity (e.g., boron) employing a plasma enhanced CVD method, and p-i-n junctions are formed.

Note that before forming the first impurity semiconductor layer 220 and the second impurity semiconductor layer 221 employing a plasma enhanced CVD method or the like, a layer such as a native oxide layer formed on the second single crystal semiconductor layer 122 that is different from the semiconductor is removed. The native oxide layer can be removed employing wet etching using hydrofluoric acid or dry etching. Further, at the time of forming the first impurity semiconductor layer 220 and the second impurity semiconductor layer 221, plasma treatment is performed using a mixed gas of hydrogen and a noble gas, for example, a mixed gas of hydrogen and helium or a mixed gas of hydrogen, helium, and argon, before a semiconductor material gas is introduced. By such plasma treatment, a native oxide layer or an element in the atmosphere (oxygen, nitrogen, or carbon) can be removed.

In this embodiment, crystallinity of the first impurity semiconductor layer 220 and the second impurity semiconductor layer 221 which are formed over the second single crystal semiconductor layer 122 may be improved by heat treatment or laser irradiation, and the first impurity semiconductor layer 220 and the second impurity semiconductor layer 221 may be activated. Note that impurities included in the impurity semiconductor layers can be diffused into the surface layer of the second single crystal semiconductor layer 122 by the heat treatment or the laser irradiation, and semiconductor junctions can be formed in a single crystal layer, so that a good bonding interface can be obtained.

In this embodiment, a lift-off method with the use of a photoresist is given as an example; however, the structure illustrated in FIG. 14C may be formed performing a film formation process of the impurity semiconductor layers, a photolithography process, an etching process, and the like.

As the structure illustrated in FIG. 16B, a protective film 180 to serve as a passivation layer is formed over the impurity semiconductor layers, the protective film is partly opened, and the first electrodes 240a, 240c, and 240e and the second electrodes 240b, 240d, and 240f can be provided.

In this embodiment, an example in which the first impurity semiconductor layers 230a, 230c, and 230e have n-type semiconductors, and the second impurity semiconductor layers 230b, 230d, and 230f have p-type semiconductors is described; naturally, the n-type semiconductors and the p-type semiconductors can be replaced with each other.

In this embodiment, an example in which the second single crystal semiconductor layer 122 has i-type conductivity and the p-i-n junctions are formed is described; however, the second single crystal semiconductor layer 122 can have n-type or p-type conductivity and p-n junctions can be formed. At this time, it is preferable that an impurity semiconductor layer having the same conductivity type as that of the second single crystal semiconductor layer 122 be formed using a layer including a dopant at high concentration.

In this manner, the semiconductor layers each including a dopant are selectively formed over the stack bodies in which the insulating layer, the first single crystal semiconductor layer, and the second single crystal semiconductor layer are sequentially formed over the base substrate, whereby a photoelectric conversion device provided with a plurality of impurity semiconductor layers having different conductivity types that is formed on the surface layer of the single crystal semiconductor layer and in which a base substrate side serves as a photo acceptance surface can be provided.

Note that this embodiment can be combined with any of the other embodiments, as appropriate.

### Embodiment 4

In this embodiment, an example of a method for manufacturing a photoelectric conversion device, which is different from that described in the above embodiments, will be described. Note that the description of a portion which overlaps with the above embodiments is omitted or partially simplified.

As illustrated in FIG. 7A, stack bodies formed using the insulating layer 103, the first single crystal semiconductor layer 121, the second single crystal semiconductor layer 122, the first impurity semiconductor layers 123a, 123c, and 123e, and the second impurity semiconductor layers 123b, 123d, and 123f are formed over the base substrate 110 in accordance with Embodiment 2.

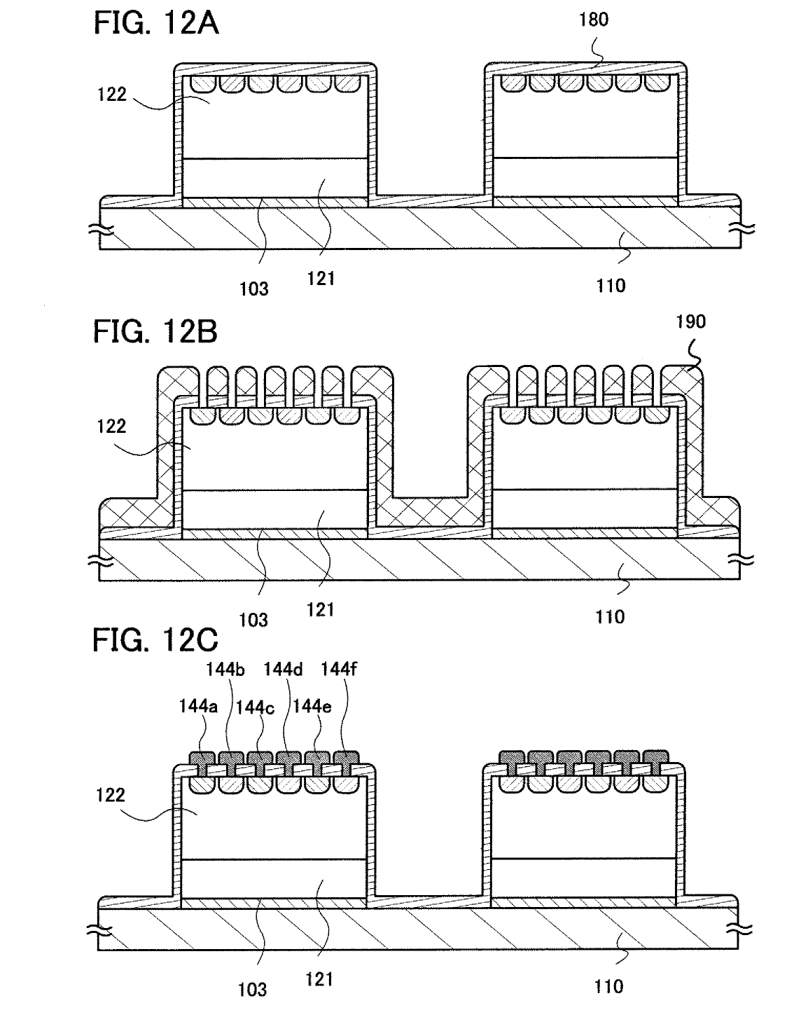

The protective film 180 to serve as a passivation layer is formed on the entire surface on an upper surface side of the base substrate 110 to be provided with the stack bodies. Then, a mask which opens parts over the impurity semiconductor layers covered with the protective film 180 is provided using a photoresist 190, and the protective film 180 in an opening is etched, whereby part of the surfaces of the impurity semiconductor layers are exposed. Then, the first electrodes 144a, 144c, and 144e and the second electrodes 144b, 144d, and 144f are formed, whereby the photoelectric conversion device is completed (see FIGS. 12A, 12B, and 12C).

A semiconductor surface has a lot of surface levels in a state which can be referred to as a lattice defect, and carriers are recombined at the vicinity of the surface; therefore, carriers in the semiconductor surface have a shorter lifetime than the inside of the semiconductor. Accordingly, when the surface of the semiconductor layer of the photoelectric conversion device is exposed, carriers which are generated by a photoelectric effect disappear by surface recombination, which becomes a factor of reducing conversion efficiency. It is effective to form a passivation layer and a good interface in order to reduce the surface recombination, and a blocking effect against mixture of impurities from the outside is also provided.

For the protective film to serve as a passivation layer, a silicon oxide layer, a silicon nitride layer, a silicon oxynitride layer, a silicon nitride oxide layer, or the like is employed other than a thermally oxidized film, for example. These can be formed employing a CVD method such as a plasma enhanced CVD method, a photo CVD method, or a thermal CVD method (including a low pressure CVD method and an atmospheric pressure CVD method).

In this embodiment, a silicon nitride film having a thickness of 100 nm formed employing a plasma enhanced CVD method is used for the protective film 180.

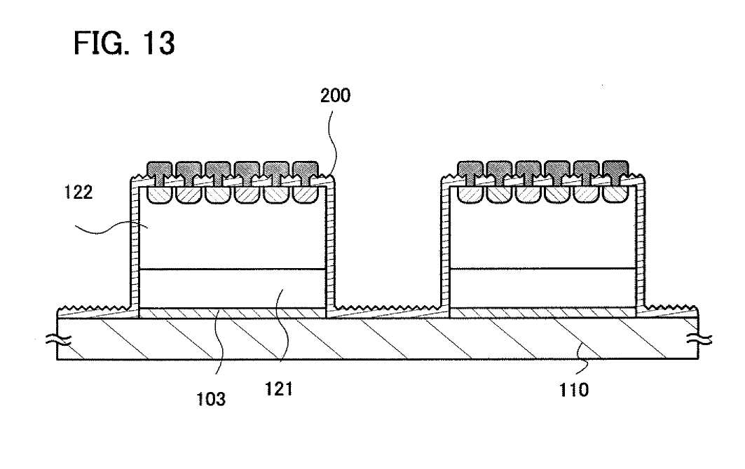

Note that unevenness may be formed on the surface layer of the protective film 180 to serve as a passivation layer. The light that penetrates the semiconductor layers reflects irregularly at the interface with the electrodes, and repeated reflection at the interface with the stack bodies, a so-called light-trapping effect, can be provided (see FIG. 13).

An example of a method for forming unevenness on the surface layer of the protective film 180 is given. First, for the protective film 180, a silicon oxide layer is formed to have a thickness of greater than or equal to 0.5 μm and less than or equal to 5 μm, more preferably, greater than or equal to 1 μm and less than or equal to 3 μm employing a CVD method. Next, unevenness 200 is formed on the surface of the protective film 180 employing a sandblast method. The structure illustrated in FIG. 13 is formed using the aforementioned technique with reference to FIGS. 12B and 12C.

As another method for forming the unevenness 200, etching with a medicine and grinding with the use of an abrasive grain, ablation with laser irradiation, or the like can be employed.

In this manner, the photoelectric conversion device according to one embodiment of the present invention is provided with the protective film to serve as a passivation layer on the surface of the stack bodies formed using the insulating layer, the first single crystal semiconductor layer, the second single crystal semiconductor layer, and the impurity semiconductor layers; and the photoelectric conversion device has a structure in which an opening of the protective film is provided in part of a region where the impurity semiconductor layers and the electrodes are in contact with each other. Since the protective film is formed, recombination of carriers on the semiconductor surface is reduced, and conversion efficiency improves. In addition, because unevenness is provided on the surface of the protective film, a light-trapping effect can be obtained and conversion efficiency can be further increased.

Note that this embodiment can be combined with any of the other embodiments, as appropriate.

### Embodiment 5

In this embodiment, an example of a method for manufacturing a photoelectric conversion device, which is different from that described in the above embodiments, will be described. Specifically, a method for forming a modified region to serve as an embrittlement layer in a single crystal semiconductor substrate with use of multiphoton absorption will be described. Note that the description of a portion which overlaps with the above embodiments is omitted or partially simplified.

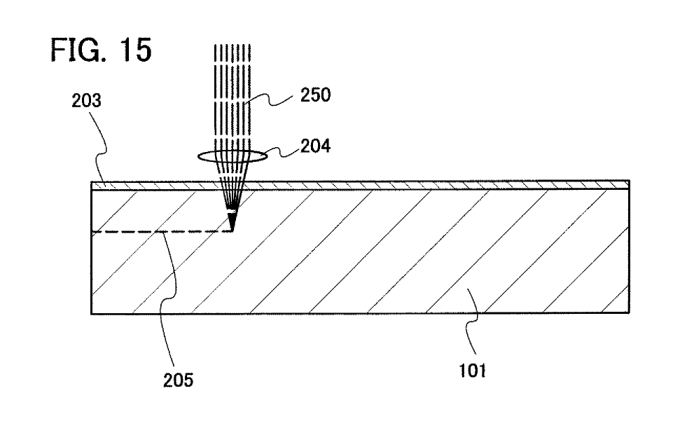

As illustrated in FIG. 15, the single crystal semiconductor substrate 101 is irradiated with a laser beam 250 from the side of the surface on which an insulating layer 203 is formed, and the laser beam 250 is condensed inside the single crystal semiconductor substrate, using an optical system 204. The single crystal semiconductor substrate 101 is irradiated with the laser beam 250, so that a modified region 205 is formed in a region at a predetermined depth of the single crystal semiconductor substrate 101. A laser beam which produces multiphoton absorption is employed as the laser beam 250. The modified region 205 has the same state as the embrittlement layer 105.

The multiphoton absorption is a phenomenon that a substance absorbs multiple photons at the same time and energy of the substance has a higher energy level than energy before light absorption. As the laser beam 250 that allows multiphoton absorption, a laser beam emitted from a femtosecond laser is used. Multiphoton absorption is known as one of the nonlinear interactions which are made by a femtosecond laser. Multiphoton absorption can generate reaction in a localized region near the focal point, and thus the modified region can be formed in a desired region. For example, irradiation with the laser beam 250 that allows multiphoton absorption can form the modified region 205 having voids with several nanometers.

In the formation of the modified region 205 utilizing multiphoton absorption, the depth of the modified region 205 formed in the single crystal semiconductor substrate 101 is determined depending on the position of the focal point of the laser beam 250 (the depth at which the laser beam 250 is focused in the single crystal semiconductor substrate 101). The position at which the laser beam 250 is focused can be set freely by a practitioner, utilizing the optical system 204.

As in this embodiment, the modified region 205 is formed using multiphoton absorption, and damages to regions other than the modified region 205 and generation of crystal defects can be prevented. Thus, a single crystal semiconductor layer having favorable characteristics such as crystallinity can be formed by being sliced at the modified region 205.

Note that it is preferable that the insulating layer 203 of an oxide layer such as a silicon oxide layer or a silicon oxynitride layer be formed over the single crystal semiconductor substrate 101, and irradiation with the laser beam 250 be conducted through the insulating layer 203. Further, the following formula (1) is preferably satisfied where the wavelength of the laser beam 250 is λ (nm), the refractive index of the insulating layer 203 at the wavelength λ (nm) is n, and the thickness of the insulating layer 203 is d (nm).

d=λ/4n×(2m+1) (m: an integer and greater than 0) [formula 1]

By forming the insulating layer 203 so as to satisfy the formula (1), reflection of the laser beam 250 on the surface of the object (the single crystal semiconductor substrate 101) can be suppressed. As a result, the modified region 205 can be efficiently formed inside the single crystal semiconductor substrate 101.

After the modified region 205 is formed, the photoelectric conversion device can be formed in accordance with any of the other embodiments.

Note that the slicing of the single crystal semiconductor substrate 101 can be conducted by application of external force instead of heat treatment. Specifically, physical and external force is applied, whereby the thin single crystal semiconductor substrate 101 can be separated at the modified region 205. For example, the thin single crystal semiconductor substrate 101 can be separated with a hand of a human or a tool. The modified region 205 is weakened due to voids or the like formed by irradiation with the laser beam 250. Therefore, by application of physical force (external force) to the single crystal semiconductor substrate 101, a weakened portion such as the voids in the modified region 205 as a trigger or a starting point causes or allows the single crystal semiconductor substrate 101 to be separated at the modified region 205. The single crystal semiconductor substrate 101 can be separated also by combination of heat treatment and application of external force. The separation of the single crystal semiconductor substrate 101 by application of external force makes it possible to reduce time needed for the slicing, which can lead to improvement in productivity.

Note that this embodiment can be combined with any of the other embodiments, as appropriate.

### Embodiment 6

In this embodiment, an example of a method for manufacturing a photoelectric conversion device, which is different from that described in the above embodiments, will be described. Note that the description of a portion which overlaps with the above embodiments is omitted or partially simplified.

As illustrated in FIG. 3C, the single crystal semiconductor substrate 101 in which the embrittlement layer 105 is formed in a region at a predetermined depth and the insulating layer 103 is formed over one surface is formed in accordance with Embodiment 2.

Next, a planarization process is conducted to the surface of the insulating layer 103 formed over the single crystal semiconductor substrate 101 by plasma treatment.

Specifically, an inert gas (e.g., an Ar gas) and/or a reaction gas (e.g., an O₂ gas or an N₂ gas) are/is introduced into a vacuum chamber, bias voltage is applied to an object to be treated (here, the single crystal semiconductor substrate 101 provided with the insulating layer 103), and plasma is emitted. In plasma, an electron and a cation of Ar are present, and the cation of Ar is accelerated in a cathode direction (toward the single crystal semiconductor substrate 101 provided with the insulating layer 103). The accelerated cation of Ar collides with the surface of the insulating layer 103 so that the surface of the insulating layer 103 is etched by sputtering. At this time, a projection of the surface of the insulating layer 103 is preferentially etched by sputtering; thus, planarity of the surface of the insulating layer 103 can be improved. In the case where a reaction gas is introduced, a defect generated due to the sputter etching performed on the surface of the insulating layer 103 can be repaired.

By the planarization treatment with use of plasma treatment, the average surface roughness (Ra) of the surface of the insulating layer 103 can be, for example, 5 nm or less, preferably 0.3 nm or less. In addition, the maximum peak-to-valley height (P-V) is 6 nm or less, preferably 3 nm or less.

As an example of the plasma treatment, the following conditions can be used: an electric power used for treatment is greater than or equal to 100 W and less than or equal to 1000 W, a pressure is greater than or equal to 0.1 Pa and less than or equal to 2.0 Pa, a gas flow rate is greater than or equal to 5 sccm and less than or equal to 150 seem, and a bias voltage is greater than or equal to 200 V and less than or equal to 600 V.

After the planarization treatment, as illustrated in FIG. 4A, the surface of the insulating layer 103 formed over the single crystal semiconductor substrate 101 and the surface of the base substrate 110 are bonded so that the single crystal semiconductor substrate 101 is attached over the base substrate 110. In this embodiment, the planarity of the surface of the insulating layer 103 is improved so that a strong bonding can be formed.

The planarization treatment described in this embodiment may be conducted to the base substrate 110 side. Specifically, plasma treatment is conducted with application of a bias voltage to the base substrate 110 to improve the planarity.

Note that this embodiment can be combined with any of the other embodiments, as appropriate.

### Embodiment 7

In this embodiment, an example of a method for manufacturing a photoelectric conversion device, which is different from that described in the above embodiments, will be described. Note that the description of a portion which overlaps with the above embodiments is omitted or partially simplified.

As illustrated in FIG. 5B, stack bodies formed using the insulating layer 103, the first single crystal semiconductor layer 121, and the second single crystal semiconductor layer 122 are formed over the base substrate 110 in accordance with Embodiment 2.

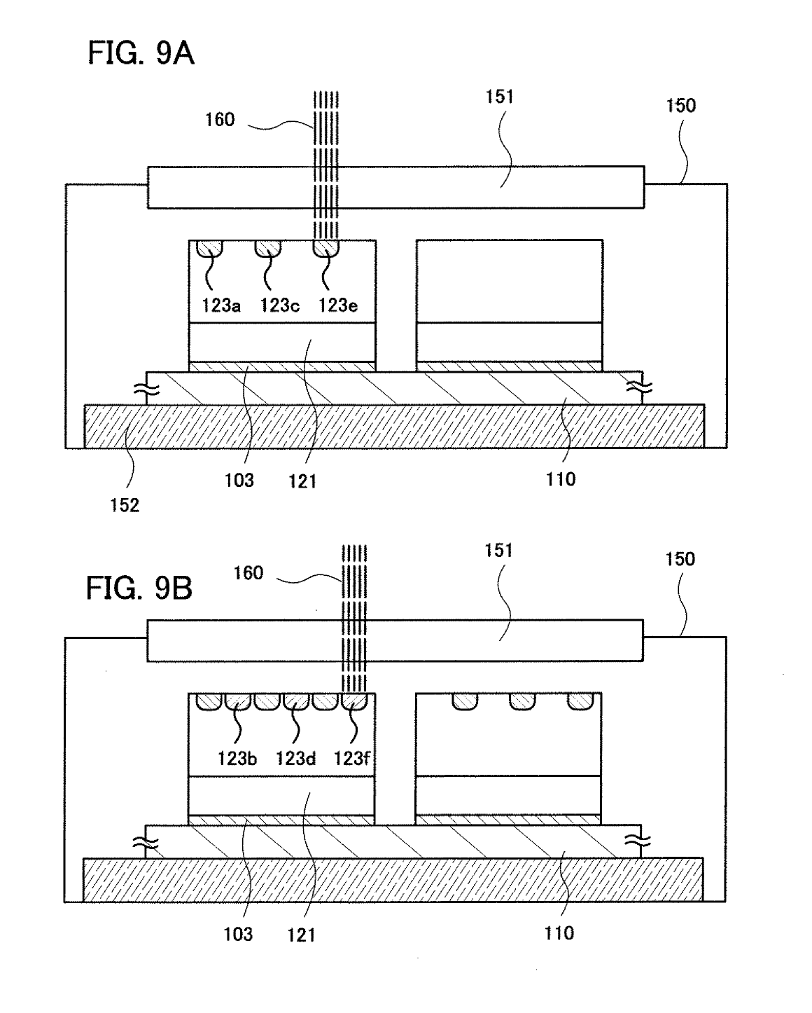

The base substrate 110 is placed in a vacuum chamber 150 provided with a window 151 for laser irradiation and a heater 152 for substrate heating where the stack bodies are laid face up, the atmosphere in the vacuum chamber 150 is replaced with a doping gas, and the laser beam 160 is selectively delivered, whereby an impurity semiconductor region is formed (see FIGS. 9A and 9B).

When the single crystal semiconductor layer is irradiated with a laser beam having a wavelength that is absorbed by the single crystal semiconductor layer, a phenomenon of melting and solidifying occurs in the vicinity of the surface. This process of melting and solidifying is strongly affected by an atmosphere, and, in some cases, an element included in the atmosphere is taken in the semiconductor layer to be melted as impurities. In this phenomenon, an impurity element taken in the semiconductor layer can change a conductivity type in the case where the impurity element is a Group 13 element or a Group 15 element. Therefore, when this method is used, even if a special apparatus such as an ion doping apparatus or an ion implantation apparatus is not used, the impurity can be introduced in the semiconductor layer.

Note that as an impurity which imparts n-type conductivity to the semiconductor layer, phosphorus (P), arsenic (As), and antimony (Sb) which belong to Group 15 elements, can be given. In addition, as an impurity which imparts p-type conductivity to the semiconductor layer, boron (B), aluminum (Al), and gallium (Ga) which belong to Group 13 elements can be given.

In addition, as a compound gas including the aforementioned impurity element, phosphine (PH₃), phosphorus trifluoride (PF₃), phosphorus trichloride (PCl_{S}), arsine (AsH₃), arsenic trifluoride (AsF₃), arsenic trichloride (AsCl₃), stibine (SbH₃), antimony trichloride (SbCl₃), and the like which includes Group 15 elements can be given. Diborane (B₂H₆), boron trifluoride (BF₃), boron trichloride (BCl₃), aluminum trichloride (AlCl₃), gallium trichloride (GaCl₃), and the like which includes Group 13 elements can be given.

Alternatively, as a compound gas including the impurity element, a mixed gas diluted with hydrogen, nitrogen, and/or a noble gas may be used in order to adjust concentration of the impurity to be introduced into the semiconductor layer. The mixed gas may be used under reduced pressure.

When the impurity semiconductor layer which is formed first has n-type conductivity, the atmosphere of the vacuum chamber 150 is replaced with a mixed gas in which phosphine that is an n-type dopant gas is diluted with hydrogen, and the semiconductor layer is irradiated with a laser beam in a band shape, whereby the first impurity semiconductor layers 123a, 123c, and 123e are formed. Next, the atmosphere of the vacuum chamber 150 is replaced with a mixed gas in which diborane that is a p-type dopant gas is diluted with helium, and the semiconductor layer is irradiated with the laser beam 160 in a band shape, whereby the second impurity semiconductor layers 123b, 123d, and 123f are formed and the structure illustrated in FIG. 7A is formed.

As for a laser and an irradiation method which can be used in this embodiment, a means which can be used for the recovery of crystallinity on the surface of the first single crystal semiconductor layer 121 in Embodiment 2 can be used.

Alternatively, as a means which is used to promote a process of melting and solidifying in laser irradiation, a substrate may be heated with the heater 152 for substrate heating. Heating a substrate has an effect of decreasing melt threshold energy at the time of laser irradiation, extending time needed for solidification, and increasing activation ratio of impurities. The substrate temperature can be set at a temperature that does not exceed a strain point of the base substrate.

In this embodiment, an n-type impurity semiconductor layer and a p-type impurity semiconductor layer are sequentially formed; however, the order may be reversed. In order to perform an operation process efficiently, a process may be used in which an impurity semiconductor layer having one conductivity type is formed for a plurality of substrates in succession, and then an impurity semiconductor layer having a conductivity type which is opposite to the one conductivity type is formed for the plurality of substrates in succession.

After that, the photoelectric conversion device can be formed in accordance with any of the other embodiments.

In this way, the stack bodies which are formed using the insulating layer, the first single crystal semiconductor layer, and the second single crystal semiconductor layer over the base substrate is selectively irradiated with a laser beam in a gas atmosphere including an impurity to serve as a dopant, whereby a plurality of impurity semiconductor layers which has different conductivity types can be formed in the surface layer of the single crystal semiconductor layer. In addition, with selective laser irradiation, the position where the impurity semiconductor layer is formed can be determined; therefore, a positioning means of a photoresist, a protective film, or the like is unnecessary, and the photoelectric conversion device with high productivity can be manufactured at low cost.

Note that this embodiment can be combined with any of the other embodiments, as appropriate.

### Embodiment 8

In this embodiment, an example of a method for manufacturing a photoelectric conversion device, which is different from that described in the above embodiments, will be described. Note that the description of a portion which overlaps with the above embodiments is omitted or partially simplified.

As illustrated in FIG. 5B, stack bodies formed using the insulating layer 103, the first single crystal semiconductor layer 121, and the second single crystal semiconductor layer 122 are formed over the base substrate 110 in accordance with Embodiment 2.

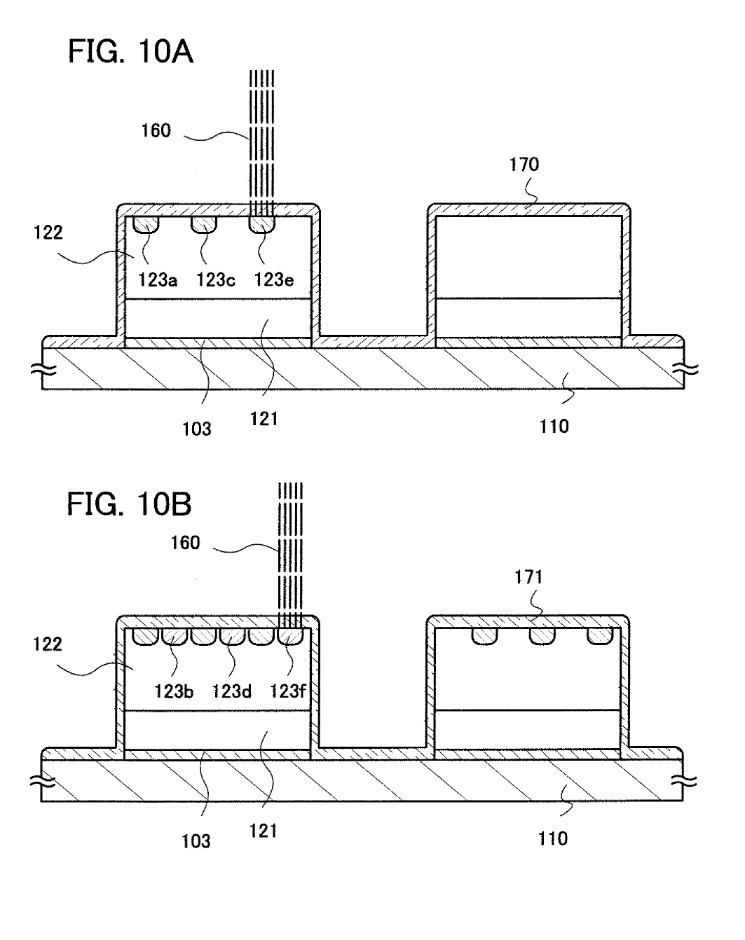

A chemical solution 170 including impurities which impart one conductivity type to a semiconductor and a chemical solution 171 including impurities which impart a conductivity type which is opposite to the one conductivity type to the semiconductor are applied to the upper surface of the stack bodies, and a laser beam is selectively delivered, whereby impurity semiconductor layers are formed (see FIGS. 10A and 10B).

When the single crystal semiconductor layer is irradiated with a laser beam having a wavelength that is absorbed by the single crystal semiconductor layer, a phenomenon of melting and solidifying occurs in the vicinity of the surface. This process of melting and solidifying is strongly affected by the impurities attached to the surface, and, in some cases, an impurity element attached to the surface is taken in a melted semiconductor layer as the impurities. In this phenomenon, the impurity element taken in the semiconductor layer can change a conductivity type in the case where the impurity element is a Group 13 element or a Group 15 element. Therefore, when this method is used, even if a special apparatus such as an ion doping apparatus or an ion implantation apparatus is not used, the impurity can be introduced in the semiconductor layer.

Note that as the impurities which change the conductivity type of the semiconductor layer into n-type conductivity, phosphorus (P) which is a Group 15 element and boron (B) which is a Group 13 element can be given typically.

As a chemical solution including the aforementioned impurity elements, a phosphoric acid aqueous solution, trimethyl phosphate, triethyl phosphate, tri-n-amyl phosphate, diphenyl-2-ethylhexyl phosphate, an ammonium phosphate solution, a boric acid solution, trimethyl borate, triethyl borate, triisopropyl borate, tripropyl borate, tri-n-octyl borate, an ammonium borate solution, or the like can be used.

The chemical solution is a salt aqueous solution or an ester compound which is hydrolyzed into salt and alcohol, and can be easily cleaned only with pure water without special cleaning fluid.

Specifically, when the impurity semiconductor layer which is formed first has n-type conductivity, using a spin coater, a slit coater, or a dip coater, an ammonium phosphate solution including an element to serve as an n-type dopant is applied to the surfaces of the stack bodies and the base substrate 110 and then dried. Then, the semiconductor layer is irradiated with a laser beam in a band shape, so that the first impurity semiconductor layers 123a, 123c, and 123e are formed. Next, using a spin coater, a slit coater, or a dip coater, an ammonium borate solution including an element to serve as a p-type dopant is applied to the surfaces of the stack bodies and the base substrate 110 and then dried. Then, the semiconductor layer is irradiated with a laser beam in a band shape, so that the second impurity semiconductor layers 123b, 123d, and 123f are formed. Further, cleaning with pure water is performed, and unnecessary impurities which are attached are washed away, so that the structure illustrated in FIG. 7A is obtained.

As for a laser which can be used in this embodiment, a laser which is used for the recovery of crystallinity on the surface of the first single crystal semiconductor layer 121 in Embodiment 2 can be used.

Alternatively, as a means which is used to promote a process of melting and solidifying in laser irradiation, a substrate may be heated with the heater for substrate heating. Heating a substrate has an effect of decreasing melt threshold energy in laser irradiation, extending time needed for solidification, and increasing activation ratio of impurities. The substrate temperature can be set at a temperature that does not exceed a strain point of the base substrate.

In this embodiment, an n-type impurity semiconductor layer and a p-type impurity semiconductor layer are sequentially formed; however, the order may be reversed. In order to perform an operation process efficiently, a process may be used in which the impurity semiconductor layer having one conductivity type is formed for a plurality of substrates in succession, and then the impurity semiconductor layer having a conductivity type which is opposite to the one conductivity type is formed for the plurality of substrates in succession.

After that, the photoelectric conversion device can be formed in accordance with any of the other embodiments.

In this way, a chemical solution including impurities to serve as a dopant is applied to the stack bodies which are formed using the insulating layer, the first single crystal semiconductor layer, and the second single crystal semiconductor layer over the base substrate and laser irradiation is selectively performed, whereby a plurality of impurity semiconductor layers which has different conductivity types can be formed in the surface layer of the single crystal semiconductor layer. In addition, with selective laser irradiation, the position where the impurity semiconductor layer is formed can be determined; therefore, a positioning means of a photoresist, a protective film, or the like is unnecessary, and the photoelectric conversion device with high productivity can be manufactured at low cost.

Note that this embodiment can be combined with any of the other embodiments, as appropriate.

This application is based on Japanese Patent Application serial No. 2009-112372 filed with Japan Patent Office on May 2, 2009, the entire contents of which are hereby incorporated by reference.

What is claimed is:

1. A photoelectric conversion device comprising:
a base substrate having a light-transmitting property;
an insulating layer having a light-transmitting property over the base substrate;
a single crystal semiconductor layer over the insulating layer;
a plurality of first impurity semiconductor layers each having one conductivity type provided in a band shape in a surface layer of the single crystal semiconductor layer;
a plurality of second impurity semiconductor layers each having a conductivity type which is opposite to the one conductivity type in the surface layer of the single crystal semiconductor layer, wherein the plurality of second impurity semiconductor layers is provided in a band shape in such a manner that the plurality of first impurity semiconductor layers and the plurality of second impurity semiconductor layers are alternately provided and do not overlap with each other;
a plurality of first electrodes in contact with the plurality of first impurity semiconductor layers; and
a plurality of second electrodes in contact with the plurality of second impurity semiconductor layers.

2. The photoelectric conversion device according to claim 1, wherein a protective film is formed at least on a surface of the plurality of first impurity semiconductor layers, on a surface of the plurality of second impurity semiconductor layers, and on a surface of the single crystal semiconductor layer except for bonding portions between the plurality of first impurity semiconductor layers and the plurality of first electrodes and bonding portions between the plurality of second impurity semiconductor layers and the plurality of second electrodes.

3. The photoelectric conversion device according to claim 2, wherein the protective film is a layer selected from a silicon oxide layer, a silicon nitride layer, a silicon nitride oxide layer, and a silicon oxynitride layer.

4. The photoelectric conversion device according to claim 1, wherein the base substrate is a substrate selected from an aluminosilicate glass substrate, an aluminoborosilicate glass substrate, and a barium borosilicate glass substrate.

5. The photoelectric conversion device according to claim 1, wherein the insulating layer is a layer selected from a silicon oxide layer, a silicon nitride layer, a silicon nitride oxide layer, and a silicon oxynitride layer.

6. A photoelectric conversion device comprising:
a base substrate having a light-transmitting property;
an insulating layer having a light-transmitting property over the base substrate;
a single crystal semiconductor layer over the insulating layer;
a plurality of first impurity semiconductor layers each having one conductivity type provided in a band shape on a surface of the single crystal semiconductor layer;
a plurality of second impurity semiconductor layers each having a conductivity type which is opposite to the one conductivity type on the surface of the single crystal semiconductor layer, wherein the plurality of second impurity semiconductor layers is provided in a band shape in such a manner that the plurality of first impurity semiconductor layers and the plurality of second impurity semiconductor layers are alternately provided and do not overlap with each other;
a plurality of first electrodes in contact with the plurality of first impurity semiconductor layers; and
a plurality of second electrodes in contact with the plurality of second impurity semiconductor layers.

7. The photoelectric conversion device according to claim 6, wherein a protective film is formed at least on a surface of the plurality of first impurity semiconductor layers, on a surface of the plurality of second impurity semiconductor layers, and on the surface of the single crystal semiconductor layer except for bonding portions between the plurality of first impurity semiconductor layers and the plurality of first electrodes and bonding portions between the plurality of second impurity semiconductor layers and the plurality of second electrodes.

8. The photoelectric conversion device according to claim 7, wherein the protective film is a layer selected from a silicon oxide layer, a silicon nitride layer, a silicon nitride oxide layer, and a silicon oxynitride layer.

9. The photoelectric conversion device according to claim 6, wherein the base substrate is a substrate selected from an aluminosilicate glass substrate, an aluminoborosilicate glass substrate, and a barium borosilicate glass substrate.

10. The photoelectric conversion device according to claim 6, wherein the insulating layer is a layer selected from a silicon oxide layer, a silicon nitride layer, a silicon nitride oxide layer, and a silicon oxynitride layer.

11. A photoelectric conversion module comprising:
a base substrate having a light-transmitting property;
an insulating layer having a light-transmitting property over the base substrate;
a plurality of single crystal semiconductor layers over the insulating layer;
a plurality of first impurity semiconductor layers each having one conductivity type provided in a band shape in a surface layer of each of the plurality of single crystal semiconductor layers;
a plurality of second impurity semiconductor layers each having a conductivity type which is opposite to the one conductivity type in the surface layer of each of the plurality of single crystal semiconductor layers, wherein the plurality of second impurity semiconductor layers is provided in a band shape in such a manner that the plurality of first impurity semiconductor layers and the plurality of second impurity semiconductor layers are alternately provided and do not overlap with each other;
a plurality of first electrodes in contact with the plurality of first impurity semiconductor layers;
a plurality of second electrodes in contact with the plurality of second impurity semiconductor layers;
a first connection electrode which connects one of the plurality of first electrodes for one of the plurality of single crystal semiconductor layers and one of the plurality of second electrodes for another one of the plurality of single crystal semiconductor layers adjacent to the one of the plurality of single crystal semiconductor layers; and
a second connection electrode which connects one of the plurality of first electrodes for the one of the plurality of single crystal semiconductor layers and another one of the plurality of first electrodes for another one of the plurality of single crystal semiconductor layers adjacent to the one of the plurality of single crystal semiconductor layers.

12. The photoelectric conversion module according to claim 11, wherein a protective film is faulted at least on a surface of the of the plurality of first impurity semiconductor layers, on a surface of the plurality of second impurity semiconductor layers, and on a surface of one of the plurality of single crystal semiconductor layers except for bonding portions between the plurality of first impurity semiconductor layers and the plurality of first electrodes and bonding portions between the plurality of second impurity semiconductor layers and the plurality of second electrodes.

13. The photoelectric conversion module according to claim 12, wherein the protective film is a layer selected from a silicon oxide layer, a silicon nitride layer, a silicon nitride oxide layer, and a silicon oxynitride layer.

14. The photoelectric conversion module according to claim 11, wherein the base substrate is a substrate selected from an aluminosilicate glass substrate, an aluminoborosilicate glass substrate, and a barium borosilicate glass substrate.

15. The photoelectric conversion module according to claim 11, wherein the insulating layer is a layer selected from a silicon oxide layer, a silicon nitride layer, a silicon nitride oxide layer, and a silicon oxynitride layer.

16. A photoelectric conversion module comprising:
a base substrate having a light-transmitting property;
an insulating layer having a light-transmitting property over the base substrate;
a plurality of single crystal semiconductor layers over the insulating layer;
a plurality of first impurity semiconductor layers each having one conductivity type provided in a band shape on a surface of each of the plurality of single crystal semiconductor layers;
a plurality of second impurity semiconductor layers each having a conductivity type which is opposite to the one conductivity type on the surface of each of the plurality of single crystal semiconductor layers, wherein the plurality of second impurity semiconductor layers is provided in a band shape in such a manner that the plurality of first impurity semiconductor layers and the plurality of second impurity semiconductor layers are alternately provided and do not overlap with each other;
a plurality of first electrodes in contact with the plurality of first impurity semiconductor layers;
a plurality of second electrodes in contact with the plurality of second impurity semiconductor layers;
a first connection electrode which connects one of the plurality of first electrodes for one of the plurality of single crystal semiconductor layers and one of the plurality of second electrodes for another one of the plurality of single crystal semiconductor layers adjacent to the one of the plurality of single crystal semiconductor layers; and
a second connection electrode which connects one of the plurality of first electrodes for the one of the plurality of single crystal semiconductor layers and another one of the plurality of first electrodes for another one of the plurality of single crystal semiconductor layers adjacent to the one of the plurality of single crystal semiconductor layers.

17. The photoelectric conversion module according to claim 16, wherein a protective film is formed at least on a surface of the of the plurality of first impurity semiconductor layers, on a surface of the plurality of second impurity semiconductor layers, and on the surface of one of the plurality of single crystal semiconductor layers except for bonding portions between the plurality of first impurity semiconductor layers and the plurality of first electrodes and bonding portions between the plurality of second impurity semiconductor layers and the plurality of second electrodes.

18. The photoelectric conversion module according to claim 17, wherein the protective film is a layer selected from a silicon oxide layer, a silicon nitride layer, a silicon nitride oxide layer, and a silicon oxynitride layer.

19. The photoelectric conversion module according to claim 16, wherein the base substrate is a substrate selected from an aluminosilicate glass substrate, an aluminoborosilicate glass substrate, and a barium borosilicate glass substrate.

20. The photoelectric conversion module according to claim 16, wherein the insulating layer is a layer selected from a silicon oxide layer, a silicon nitride layer, a silicon nitride oxide layer, and a silicon oxynitride layer.

21. A method for manufacturing a photoelectric conversion module comprising the steps of:
preparing a plurality of single crystal semiconductor substrates each provided with an insulating layer on a surface and an embrittlement layer in a region at a predetermined depth, and a base substrate;
arranging the plurality of single crystal semiconductor substrates at predetermined intervals over the base substrate with the insulating layer interposed therebetween;
bonding a surface of the insulating layer and a surface of the base substrate, so that the plurality of single crystal semiconductor substrates is attached over the base substrate;
separating the plurality of single crystal semiconductor substrates at the embrittlement layer, so that a plurality of first stack bodies in which the insulating layer and a first single crystal semiconductor layer are sequentially stacked is formed over the base substrate;
performing planarization treatment on a surface of the first single crystal semiconductor layer;
forming a semiconductor layer including a second single crystal semiconductor layer so as to cover the plurality of first stack bodies and a space between the plurality of first stack bodies, the second single crystal semiconductor layer is at least partly single-crystallized over the plurality of first stack bodies;
etching the semiconductor layer selectively at the space between the plurality of first stack bodies, so that a plurality of second stack bodies in which the insulating layer, the first single crystal semiconductor layer and the second single crystal semiconductor layer are sequentially stacked is formed over the base substrate at predetermined intervals;
forming a plurality of first impurity semiconductor layers each having one conductivity type and a plurality of second impurity semiconductor layers each having a conductivity type which is opposite to the one conductivity type in a surface layer of the second single crystal semiconductor layer;
forming a plurality of first electrodes on a surface of the plurality of first impurity semiconductor layers, and a plurality of second electrodes on a surface of the plurality of second impurity semiconductor layers;
forming a first connection electrode which connects one of the plurality of first electrodes of one of the plurality of second stack bodies and one of the plurality of second electrodes of the other one of the plurality of second stack bodies between two of the plurality of second stack bodies next to each other; and
forming a second connection electrode which connects two of the plurality of first electrodes between two of the plurality of second stack bodies next to each other.

22. The method for manufacturing the photoelectric conversion module according to claim 21, wherein each of the plurality of first impurity semiconductor layers and the plurality of second impurity semiconductor layers are formed in such a manner that a laser beam is selectively delivered in a gas atmosphere including an impurity serving as a dopant and the impurity is introduced to the surface layer of the second single crystal semiconductor layer.

23. The method for manufacturing the photoelectric conversion module according to claim 22, wherein a compound gas including an impurity for forming the plurality of first impurity semiconductor layers is a compound gas selected from phosphine (PH₃), phosphorus trifluoride (PF₃), phosphorus trichloride (PCl₃), arsine (AsH₃), arsenic trifluoride (AsF₃), arsenic trichloride (AsCl₃), stibine (SbH₃), and antimony trichloride (SbCl₃).

24. The method for manufacturing the photoelectric conversion module according to claim 22, wherein a compound gas including an impurity for forming the plurality of second impurity semiconductor layers is a compound gas selected from diborane (B₂H₆), boron trifluoride (BF₃), boron trichloride (BCl₃), aluminum trichloride (AlCl₃), and gallium trichloride (GaCl₃).

25. The method for manufacturing the photoelectric conversion module according to claim 21, wherein each of the plurality of first impurity semiconductor layers and the plurality of second impurity semiconductor layers is formed in such a manner that a chemical solution including an impurity serving as a dopant is selectively applied and a laser beam is delivered so that the impurity is introduced to the surface layer of the second single crystal semiconductor layer.

26. The method for manufacturing the photoelectric conversion module according to claim 25, wherein the chemical solution including an impurity for forming the plurality of first impurity semiconductor layers is a chemical solution selected from trimethyl phosphate, triethyl phosphate, tri-n-amyl phosphate, and diphenyl-2-ethylhexyl phosphate.

27. The method for manufacturing the photoelectric conversion module according to claim 25, wherein the chemical solution including an impurity for forming the plurality of second impurity semiconductor layers is a chemical solution selected from trimethyl borate, triethyl borate, triisopropyl borate, tripropyl borate, and tri-n-octyl borate.

28. The method for manufacturing the photoelectric conversion module according to claim 21, wherein the planarization treatment is performed in such a manner that the first single crystal semiconductor layer is irradiated with a laser beam.

29. The method for manufacturing the photoelectric conversion module according to claim 21, wherein the planarization treatment is performed in such a manner that the surface layer of the first single crystal semiconductor layer is etched.

30. The method for manufacturing the photoelectric conversion module according to claim 21, wherein the insulating layer is a layer selected from a silicon oxide layer, a silicon nitride layer, a silicon nitride oxide layer, and a silicon oxynitride layer.

31. The method for manufacturing the photoelectric conversion module according to claim 21, wherein the embrittlement layer is formed in such a manner that hydrogen, helium, or a halogen is introduced to inside of each of the plurality of single crystal semiconductor substrates.

32. The method for manufacturing the photoelectric conversion module according to claim 21, wherein the base substrate is a substrate selected from an aluminosilicate glass substrate, an aluminoborosilicate glass substrate, and a barium borosilicate glass substrate.

33. A method for manufacturing a photoelectric conversion module comprising the steps of:
preparing a plurality of single crystal semiconductor substrates each provided with an insulating layer on a surface and an embrittlement layer in a region at a predetermined depth, and a base substrate;
arranging the plurality of single crystal semiconductor substrates at predetermined intervals over the base substrate with the insulating layer interposed therebetween;
bonding a surface of the insulating layer and a surface of the base substrate, so that the plurality of single crystal semiconductor substrates is attached over the base substrate;
separating the plurality of single crystal semiconductor substrates at the embrittlement layer, so that a plurality of first stack bodies in which the insulating layer and a first single crystal semiconductor layer are sequentially stacked is formed over the base substrate;
performing planarization treatment on a surface of the first single crystal semiconductor layer;
forming a semiconductor layer including a second single crystal semiconductor layer so as to cover the plurality of first stack bodies and a space between the plurality of first stack bodies, the second single crystal semiconductor layer is at least partly single-crystallized over the plurality of first stack bodies;
etching the semiconductor layer selectively at the space between the plurality of first stack bodies, so that a plurality of second stack bodies in which the insulating layer, the first single crystal semiconductor layer and the second single crystal semiconductor layer are sequentially stacked is formed over the base substrate at predetermined intervals;
forming a plurality of first impurity semiconductor layers each having one conductivity type and a plurality of second impurity semiconductor layers each having a conductivity type which is opposite to the one conductivity type on a surface of the second single crystal semiconductor layer;
forming a plurality of first electrodes on a surface of the plurality of first impurity semiconductor layers, and a plurality of second electrodes on a surface of the plurality of second impurity semiconductor layers;
forming a first connection electrode which connects one of the plurality of first electrodes and one of the plurality of second electrodes between two of the plurality of second stack bodies next to each other; and
forming a second connection electrode which connects two of the plurality of first electrodes between two of the plurality of second stack bodies next to each other.

34. The method for manufacturing the photoelectric conversion module according to claim 33, wherein each of the plurality of first impurity semiconductor layers and the plurality of second impurity semiconductor layers is formed employing a plasma enhanced CVD method using a source gas including an impurity serving as a dopant.

35. The method for manufacturing the photoelectric conversion module according to claim 33, wherein the planarization treatment is performed in such a manner that the first single crystal semiconductor layer is irradiated with a laser beam.

36. The method for manufacturing the photoelectric conversion module according to claim 33, wherein the planarization treatment is performed in such a manner that a surface layer of the first single crystal semiconductor layer is etched.

37. The method for manufacturing the photoelectric conversion module according to claim 33, wherein the insulating layer is a layer selected from a silicon oxide layer, a silicon nitride layer, a silicon nitride oxide layer, and a silicon oxynitride layer.

38. The method for manufacturing the photoelectric conversion module according to claim 33, wherein the embrittlement layer is formed in such a manner that hydrogen, helium, or a halogen is introduced to inside of each of the plurality of single crystal semiconductor substrates.

39. The method for manufacturing the photoelectric conversion module according to claim 33, wherein the base substrate is a substrate selected from an aluminosilicate glass substrate, an aluminoborosilicate glass substrate, and a barium borosilicate glass substrate.
